(19) United States
(12) Patent Application Publication
(10) Pub. No.: US 2025/0366205 A1
(43) Pub. Date: Nov. 27, 2025

(54) ACTIVE MATRIX SUBSTRATE, DISPLAY DEVICE, AND METHOD OF MANUFACTURING ACTIVE MATRIX SUBSTRATE

(71) Applicant: Sharp Display Technology Corporation, Kameyama City (JP)

(72) Inventors: Tetsuo Kikuchi, Kameyama City (JP); Tohru Daitoh, Kameyama City (JP); Masahiko Suzuki, Kameyama City (JP); Setsuji Nishimiya, Kameyama City (JP); Hitoshi Takahata, Kameyama City (JP)

(21) Appl. No.: 19/184,538

(22) Filed: Apr. 21, 2025

(30) Foreign Application Priority Data
May 21, 2024 (JP) 2024-082848

(51) Int. Cl. H10D 86/40; H10D 86/01; H10D 86/60

(52) U.S. Cl. CPC H10D 86/441; H10D 86/021; H10D 86/423; H10D 86/60

(57) ABSTRACT

An active matrix substrate includes a scanning signal line drive circuit including an oxide semiconductor TFT. The oxide semiconductor TFT includes an oxide semiconductor layer including a channel region, a first contact region, and a second contact region, a gate electrode disposed on the channel region via a gate insulating layer, a source electrode, and a drain electrode. The oxide semiconductor layer has a layered structure including a first layer and a second layer that is located between the first layer and the gate insulating layer, is an uppermost layer of the oxide semiconductor layer, and has a lower mobility than the first layer. A thickness of the second layer in the channel region is equal to or more than 3.4% of a thickness of the gate insulating layer.

### CROSS-REFERENCE TO RELATED APPLICATIONS

This application claims the benefit of priority to Japanese Patent Application Number 2024-082848 filed on May 21, 2024. The entire contents of the above-identified application are hereby incorporated by reference.

### BACKGROUND

### Technical Field

The disclosure relates to an active matrix substrate and, more particularly, to an active matrix substrate including an oxide semiconductor TFT. The disclosure relates to a display device including such an active matrix substrate, and a method of manufacturing the active matrix substrate.

An active matrix substrate used in a liquid crystal display device, an organic electroluminescence (EL) display device, or the like includes a display region including a plurality of pixels, and a non-display region positioned in a periphery of the display region (also referred to as a frame region). In the display region, a thin film transistor (hereinafter referred to as a “TFT”) is provided for each of the pixels. As a TFT provided for each of the pixels, in the related art, a TFT including an amorphous silicon film serving as an active layer (hereinafter referred to as an “amorphous silicon TFT”) and a TFT including a polycrystalline silicon film serving as an active layer (hereinafter referred to as a “polycrystalline silicon TFT”) have been widely used.

There is proposed use of an oxide semiconductor as a material of the active layer of the TFT, in place of amorphous silicon and polycrystalline silicon. Such a TFT is referred to as an “oxide semiconductor TFT”. The oxide semiconductor has a higher mobility than amorphous silicon. As such, the oxide semiconductor TFT can operate at a higher speed than the amorphous silicon TFT.

A structure of the TFT is roughly classified into a bottom gate structure and a top gate structure. Currently, the bottom gate structure is often adopted for the oxide semiconductor TFT, but it is also proposed to use the top gate structure (see, for example, JP 2013-21312 A). In the top gate structure, the gate insulating layer can be thinned, resulting in high current supply performance.

In the non-display region of the active matrix substrate, peripheral circuits including the TFT may be monolithically (integrally) formed. By forming the peripheral circuits monolithically, the non-display region can be narrowed (frame narrowing) and the mounting process can be simplified, resulting in cost reduction. For example, in the non-display region, a gate driver circuit (scanning signal line drive circuit) may be formed monolithically, and a source driver circuit (image signal line drive circuit) may be mounted by a chip on glass (COG) process. The monolithically formed gate driver circuit is referred to as a gate driver monolithic (GDM) circuit. A liquid crystal display device in which a GDM circuit is formed on an active matrix substrate is disclosed in International Publication WO 2011/055584.

In the present specification, a TFT arranged in each pixel in the display region is referred to as a “pixel TFT”. In addition, a TFT constituting a peripheral circuit provided in the non-display region is referred to as a “circuit TFT”. When the pixel TFT is an oxide semiconductor TFT, it is preferable that the circuit TFT be also an oxide semiconductor TFT from the viewpoint of the manufacturing process.

### SUMMARY

A voltage corresponding to a peak-to-peak voltage Vpp of a clock signal which is a drive signal of the GDM circuit or a voltage boosted to a level higher than the peak-to-peak voltage Vpp is applied to the circuit TFT of the GDM circuit. Therefore, when the oxide semiconductor TFT is used as the circuit TFT of the GDM circuit, the oxide semiconductor TFT is required to have a high source-drain breakdown voltage. On the other hand, in order to reduce the circuit size of the GDM circuit, the oxide semiconductor TFT is also required to have a high mobility.

However, the higher the mobility of the oxide semiconductor TFT is, the more difficult it is to ensure the source-drain breakdown voltage. That is, in the oxide semiconductor TFT, it is difficult to achieve both the high source-drain breakdown voltage and the high mobility.

An embodiment of the disclosure has been conceived in light of the above-described problem, and an object of the disclosure is to provide an active matrix substrate that includes a scanning signal line drive circuit including an oxide semiconductor TFT and can achieve both the high source-drain breakdown voltage and the high mobility of the oxide semiconductor TFT.

The present specification discloses an active matrix substrate, a display device, and a method of manufacturing the active matrix substrate, which are described in the following Items.

### Item 1

An active matrix substrate including:
a substrate;
a plurality of scanning signal lines supported by the substrate; and
a scanning signal line drive circuit configured to drive the plurality of scanning signal lines, the scanning signal line drive circuit including a plurality of oxide semiconductor TFTs,
wherein the plurality of oxide semiconductor TFTs include a plurality of first oxide semiconductor TFTs,
each of the first oxide semiconductor TFTs includes:
a first oxide semiconductor layer including a channel region, and a first contact region and a second contact region located on both sides of the channel region;
a first gate electrode disposed on the channel region of the first oxide semiconductor layer with a first gate insulating layer interposed between the first gate electrode and the first oxide semiconductor layer;
a first source electrode electrically connected to the first contact region; and
a first drain electrode electrically connected to the second contact region,
the first oxide semiconductor layer has a layered structure including a first layer and a second layer that is located between the first layer and the first gate insulating layer, is an uppermost layer of the first oxide semiconductor layer, and has a lower mobility than the first layer, and
a thickness of the second layer in the channel region is equal to or more than 3.4% of a thickness of the first gate insulating layer.

### Item 2

The active matrix substrate according to Item 1, wherein a thickness of the second layer in the channel region is equal to or more than 5 nm.

### Item 3

The active matrix substrate according to Item 1 or 2, wherein the first oxide semiconductor layer further includes a third layer located on a side opposite to the second layer with respect to the first layer, the third layer having a lower mobility than the first layer.

### Item 4

The active matrix substrate according to any one of Items 1 to 3, wherein the plurality of first oxide semiconductor TFTs include at least a pair of first oxide semiconductor TFTs connected in series.

### Item 5

The active matrix substrate according to any one of Items 1 to 4,
wherein the plurality of oxide semiconductor TFTs include an oxide semiconductor TFT having a first channel length CL1, and
the plurality of first oxide semiconductor TFTs include a first oxide semiconductor TFT having a second channel length CL2 larger than the first channel length CL1.

### Item 6

The active matrix substrate according to any one of Items 1 to 5,
wherein the plurality of oxide semiconductor TFTs further include a plurality of second oxide semiconductor TFTs, and
each of the second oxide semiconductor TFTs includes:
a second oxide semiconductor layer different from the first oxide semiconductor layer, the second oxide semiconductor layer having a lower mobility than the first layer of the first oxide semiconductor layer; and
a second gate electrode disposed on a part of the second oxide semiconductor layer with a second gate insulating layer interposed between the second gate electrode and the second oxide semiconductor layer.

### Item 7

The active matrix substrate according to Item 6, wherein the plurality of second oxide semiconductor TFTs include at least one pair of second oxide semiconductor TFTs connected in series.

### Item 8

The active matrix substrate according to Item 6 or 7,
wherein the plurality of oxide semiconductor TFTs include an oxide semiconductor TFT having a first channel length CL1, and
the plurality of second oxide semiconductor TFTs include a second oxide semiconductor TFT having a second channel length CL2 larger than the first channel length CL1.

### Item 9

The active matrix substrate according to any one of Items 1 to 8, wherein the first gate insulating layer overlaps neither the first contact region nor the second contact region of the first oxide semiconductor layer in a plan view.

### Item 10

The active matrix substrate according to any one of Items 1 to 9, further including an upper insulating layer covering the first oxide semiconductor layer and the first gate electrode,
wherein the upper insulating layer includes a source contact hole for electrically connecting the first source electrode to the first contact region and a drain contact hole for electrically connecting the first drain electrode to the second contact region, and
the second layer of the first oxide semiconductor layer is present at least in a region of the first contact region not overlapping the source contact hole, and is present at least in a region of the second contact region not overlapping the drain contact hole.

### Item 11

The active matrix substrate according to any one of Items 1 to 10,
wherein the second layer of the first oxide semiconductor layer is removed in a part of the first contact region and a part of the second contact region, and
the first source electrode and the first drain electrode each are in direct contact with the first layer of the first oxide semiconductor layer.

### Item 12

The active matrix substrate according to any one of Items 1 to 11, wherein the scanning signal line drive circuit is monolithically formed on the active matrix substrate.

### Item 13

The active matrix substrate according to any one of Items 1 to 12, wherein the first oxide semiconductor layer includes an In—Ga—Zn—O-based semiconductor.

### Item 14

A display device including the active matrix substrate according to any one of Items 1 to 13.

### Item 15

A method of manufacturing the active matrix substrate according to any one of Items 1 to 13, including:
(A) forming the first oxide semiconductor layer;
(B) after the (A), depositing an insulating film on the first oxide semiconductor layer; and
(C) after the (B), forming the first gate insulating layer by etching the insulating film,
wherein a thickness of the second layer of the first oxide semiconductor layer formed in the (A) is set to cause the second layer to remain over an entire region serving as the first contact region and an entire region serving as the second contact region when the (C) is completed.

According to an embodiment of the disclosure, there is provided an active matrix substrate that includes a scanning signal line drive circuit including an oxide semiconductor TFT and can achieve both a high source-drain breakdown voltage and a high mobility of the oxide semiconductor TFT.

### BRIEF DESCRIPTION OF DRAWINGS

The disclosure will be described with reference to the accompanying drawings, wherein like numbers reference like elements.

FIG. 1 is a schematic cross-sectional view schematically illustrating a liquid crystal display device 100 according to an embodiment of the disclosure.

FIG. 2 is a schematic plan view schematically illustrating the liquid crystal display device 100.

FIG. 3 is an equivalent circuit diagram of one pixel P of the liquid crystal display device 100.

FIG. 4 is a cross-sectional view schematically illustrating a TFT substrate 10 included in the liquid crystal display device 100, and illustrating a region corresponding to a circuit TFT 3.

FIG. 5A is a process cross-sectional view for illustrating a manufacturing method of the TFT substrate 10.

FIG. 5B is a process cross-sectional view for illustrating the manufacturing method of the TFT substrate 10.

FIG. 5C is a process cross-sectional view for illustrating the manufacturing method of the TFT substrate 10.

FIG. 5D is a process cross-sectional view for illustrating the manufacturing method of the TFT substrate 10.

FIG. 5E is a process cross-sectional view for illustrating the manufacturing method of the TFT substrate 10.

FIG. 5F is a process cross-sectional view for illustrating the manufacturing method of the TFT substrate 10.

FIG. 5G is a process cross-sectional view for illustrating the manufacturing method of the TFT substrate 10.

FIG. 5H is a process cross-sectional view for illustrating the manufacturing method of the TFT substrate 10.

FIG. 6 is a cross-sectional view schematically illustrating another TFT substrate 10A used in the liquid crystal display device 100, and illustrates a region corresponding to two circuit TFTs 3A and TFT 3B of the circuit TFTs included in a gate driver 40.

FIG. 7A is a process cross-sectional view for illustrating a manufacturing method of the TFT substrate 10A.

FIG. 7B is a process cross-sectional view for illustrating the manufacturing method of the TFT substrate 10A.

FIG. 7C is a process cross-sectional view for illustrating the manufacturing method of the TFT substrate 10A.

FIG. 7D is a process cross-sectional view for illustrating the manufacturing method of the TFT substrate 10A.

FIG. 7E is a process cross-sectional view for illustrating the manufacturing method of the TFT substrate 10A.

FIG. 7F is a process cross-sectional view for illustrating the manufacturing method of the TFT substrate 10A.

FIG. 7G is a process cross-sectional view for illustrating the manufacturing method of the TFT substrate 10A.

FIG. 7H is a process cross-sectional view for illustrating the manufacturing method of the TFT substrate 10A.

FIG. 7I is a process cross-sectional view for illustrating the manufacturing method of the TFT substrate 10A.

FIG. 7J is a process cross-sectional view for illustrating the manufacturing method of the TFT substrate 10A.

FIG. 8 is a cross-sectional view schematically illustrating still another TFT substrate 10B used in the liquid crystal display device 100, and illustrates a region corresponding to a certain circuit TFT 3 of the circuit TFTs included in the gate driver 40.

FIG. 9 is a schematic plan view schematically illustrating a liquid crystal display device 100A including a first gate driver 40A and a second gate driver 40B.

FIG. 10 is a diagram illustrating an overall configuration of the first gate driver 40A and the second gate driver 40B.

FIG. 11 is a schematic circuit diagram illustrating a configuration of the first gate driver 40A.

FIG. 12 is a circuit diagram illustrating a basic configuration of a unit circuit including a bistable circuit SR(n).

FIG. 13 is a circuit diagram illustrating a detailed configuration of a unit circuit including the bistable circuit SR(n).

FIG. 14 is a circuit diagram illustrating a detailed configuration of a unit circuit including the bistable circuit SR(n).

### DESCRIPTION OF EMBODIMENTS

Hereinafter, embodiments of the disclosure will be described with reference to the accompanying drawings. Note that hereinafter, a liquid crystal display device will be described as an example of a display device according to embodiments of the disclosure. However, the display device according to embodiments of the disclosure is not limited to a liquid crystal display device. For example, the display device according to the embodiments of the disclosure may be an organic EL display device. In addition, a thin film transistor in the following description is an n-type TFT, and an electrical connection relationship in the case of using the n-type TFT will be described. It should be noted that the electrical connection between the source and the drain of a p-type TFT is opposite to the electrical connection between the source and the drain of the n-type TFT.

### Schematic Configuration of Liquid Crystal Display Device

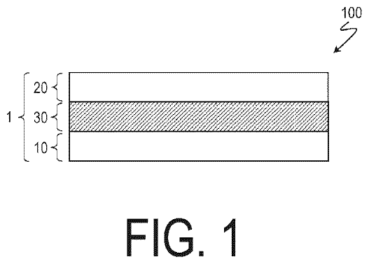

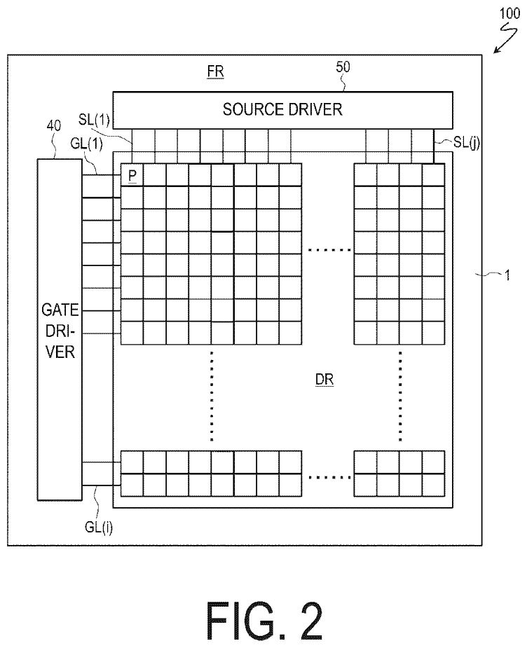

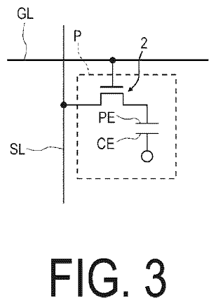

First a liquid crystal display device 100 according to an embodiment of the disclosure will be described with reference to FIG. 1, FIG. 2, and FIG. 3. FIG. 1 and FIG. 2 are a schematic cross-sectional view and a schematic plan view schematically illustrating the liquid crystal display device 100, respectively. FIG. 3 is an equivalent circuit diagram of one pixel P of the liquid crystal display device 100.

As illustrated in FIG. 1, the liquid crystal display device 100 includes a display panel 1. The display panel 1 includes an active matrix substrate (hereinafter, referred to as a “TFT substrate”) 10, a counter substrate (also referred to as a “color filter substrate”) 20 disposed so as to face the TFT substrate 10, and a liquid crystal layer 30 provided between the TFT substrate 10 and the counter substrate 20.

The liquid crystal display device 100, as illustrated in FIG. 2, includes a display region DR and a non-display region (also referred to as a “peripheral region” or a “frame region”) FR. The display region DR is defined by a plurality of pixels P. The plurality of pixels P are arrayed in a matrix shape including a plurality of rows and a plurality of columns. The non-display region FR is a region positioned in a periphery of the display region DR and does not contribute to display.

The display panel 1 (more specifically, the TFT substrate 10) of the liquid crystal display device 100 includes a plurality of (i) gate bus lines (scanning signal lines) GL(1) to GL(i) and a plurality of (j) source bus lines (image signal lines) SL(1) to SL(j). The gate bus lines GL(1) to GL(i) (which may be collectively referred to as a “gate bus line GL”) extend in the row direction, whereas the source bus lines SL(1) to SL(j) (which may be collectively referred to as a “source bus line SL”) extend in the column direction (a direction substantially orthogonal to the row direction). The gate bus line GL and the source bus line SL are supported by a substrate 11 described later.

As illustrated in FIG. 3, each of the pixels P is provided with a thin film transistor (pixel TFT) 2, and a pixel electrode PE. The pixel TFT 2 is supplied with a scanning signal (gate signal) from the corresponding gate bus line GL, and is supplied with an image signal (source signal) from the corresponding source bus line SL. The pixel TFT 2 is an oxide semiconductor TFT including an oxide semiconductor layer as an active layer. The pixel electrode PE is electrically connected to the pixel TFT 2. A common electrode CE is arranged so as to face the pixel electrode PE.

The liquid crystal display device 100 further includes a gate driver (a scanning signal line drive circuit) 40 for driving the gate bus lines GL(1) to GL(i) and a source driver (an image signal line drive circuit) 50 for driving the source bus lines SL(1) to SL(j). The gate driver 40 and the source driver 50 are arranged in the non-display region FR.

The gate driver 40 sequentially brings the plurality of gate bus lines GL(1) to GL(i) into a selected state (a state in which the high-level potential of the scanning signal is applied). Here, the gate driver 40 is monolithically formed on the active matrix substrate 10. In other words, the gate driver 40 is a GDM circuit.

The gate driver 40 includes a plurality of circuit TFTs. Like the pixel TFT 2, each circuit TFT is an oxide semiconductor TFT.

### Structure of Circuit TFT

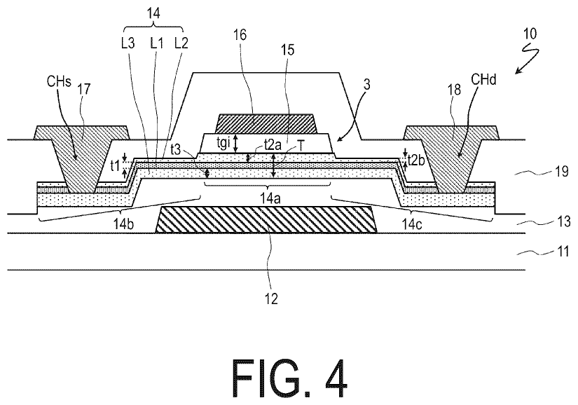

The structure of the circuit TFT included in the gate driver 40 will be described with reference to FIG. 4. FIG. 4 is a cross-sectional view schematically illustrating the TFT substrate 10, and illustrating a region corresponding to a circuit TFT 3.

As illustrated in FIG. 4, the TFT substrate 10 includes the substrate 11, a light blocking layer 12, and the circuit TFT 3. Although one circuit TFT 3 is illustrated here, the TFT substrate 10 includes a plurality of circuit TFTs 3 each having the structure illustrated in FIG. 4.

The substrate 11 is transparent and has insulating properties. The substrate 11 is, for example, a glass substrate or a plastic substrate. The substrate 11 supports the circuit TFT 3 and the like.

The light blocking layer 12 is provided on the substrate 11. The light blocking layer 12 is formed of a material (for example, metal material) having light blocking properties and electrical conductivity. A lower insulating layer 13 is provided covering the light blocking layer 12.

The circuit TFT 3 includes an oxide semiconductor layer 14 provided on the lower insulating layer 13, a gate insulating layer 15 provided on the oxide semiconductor layer 14, and a gate electrode 16 arranged to face the oxide semiconductor layer 14 with the gate insulating layer 15 interposed therebetween. The circuit TFT 3 further includes a source electrode 17 and a drain electrode 18 that are electrically connected to the oxide semiconductor layer 14.

The oxide semiconductor layer 14 includes a channel region 14a, and a source contact region (first contact region) 14b and a drain contact region (second contact region) 14c that are positioned respectively on both sides of the channel region 14a. The channel region 14a overlaps the gate insulating layer 15 and the gate electrode 16 in a plan view. The source contact region 14b and the drain contact region 14c do not overlap the gate insulating layer 15 and the gate electrode 16 in a plan view, and have a lower specific resistance than the channel region 14a. The source contact region 14b and the drain contact region 14c can be formed by, for example, performing resistance reduction processing on the oxide semiconductor layer 14 using the gate electrode 16 and the gate insulating layer 15 as a mask.

The gate insulating layer 15 is formed on the oxide semiconductor layer 14 and overlaps the channel region 14a in a plan view. That is, the gate insulating layer 15 is removed on the source contact region 14b and the drain contact region 14c.

The gate electrode 16 is disposed on the channel region 14a of the oxide semiconductor layer 14 with the gate insulating layer 15 interposed therebetween. An upper insulating layer 19 is provided so as to cover the oxide semiconductor layer 14, the gate insulating layer 15, and the gate electrode 16.

The source electrode 17 and the drain electrode 18 are formed on the upper insulating layer 19. The source electrode 17 is electrically connected to the source contact region 14b, and the drain electrode 18 is electrically connected to the drain contact region 14c. The source electrode 17 is connected to the source contact region 14b in a source contact hole CHs formed in the upper insulating layer 19 and the like, and the drain electrode 18 is connected to the drain contact region 14c in a drain contact hole CHd formed in the upper insulating layer 19 and the like.

The light blocking layer 12 is disposed below the oxide semiconductor layer 14 and faces the channel region 14a of the oxide semiconductor layer 14 with the lower insulating layer 13 interposed therebetween. The light blocking layer 12 may be in an electrically floating state or may function as a lower gate electrode when a predetermined potential is applied thereto. When the light blocking layer 12 functions as the lower gate electrode, for example, the same potential as that of the gate electrode 16 can be applied to the light blocking layer 12.

In the present embodiment, the oxide semiconductor layer 14 has a layered structure. In the example illustrated, the oxide semiconductor layer 14 includes a first layer L1, a second layer L2 located between the first layer L1 and the gate insulating layer 15, and a third layer L3 located on the opposite side of the second layer L2 with respect to the first layer L1. That is, the oxide semiconductor layer 14 has a triple-layer structure. The first layer L1, the second layer L2, and the third layer L3 are arranged on the lower insulating layer 13 in the order of the third layer L3, the first layer L1, and the second layer L2. Therefore, it can be said that the first layer L1, the second layer L2, and the third layer L3 are an “intermediate layer”, an “upper layer”, and a “lower layer”, respectively.

As can be seen from the above description, the second layer L2 is the uppermost layer of the oxide semiconductor layer 14. The second layer L2 has a lower mobility than the first layer L1.

As can be seen from the above description, the third layer L3 is the lowermost layer of the oxide semiconductor layer 14. The third layer L3 also has a lower mobility than the first layer L1.

Thus, the second layer L2 and the third layer L3 each have a lower mobility than the first layer L1. In other words, the first layer L1 has a higher mobility than the second layer L2 and the third layer L3. That is, the first layer L1 has a lower band gap lower than the second layer L2 and the third layer L3. Note that the first layer L1 may have a relatively high mobility, and the mobility of the first layer L1 is not particularly limited. The mobility of the first layer L1 is, for example, equal to or more than 10 cm²/Vs.

As illustrated in FIG. 4, a thickness t2b of the second layer L2 in the source contact region 14b and the drain contact region 14c is smaller than a thickness t2a of the second layer L2 in the channel region 14a. This is because when the insulating film to be the gate insulating layer 15 is patterned by etching, the second layer L2 in the regions to be the source contact region 14b and the drain contact region 14c is also etched.

In the present embodiment, the thickness t2a of the second layer L2 in the channel region 14a is set to satisfy a predetermined relationship with a thickness tgi of the gate insulating layer 15. To be specific, the thickness t2a of the second layer L2 in the channel region 14a is equal to or more than 3.4% of the thickness tgi of the gate insulating layer 15.

Although not illustrated here, the circuit TFT 3 and the pixel TFT 2 are covered with an interlayer insulating layer. A pixel electrode PE is provided on the interlayer insulating layer in the display region DR. The pixel electrode PE is formed of a transparent conductive material (e.g., ITO or IZO). When the display mode of the liquid crystal display device 100 is an FFS mode (which is a kind of transverse electrical field mode), the TFT substrate 10 further includes the common electrode CE opposed to the pixel electrode PE via a dielectric layer. The common electrode CE is formed of a transparent conductive material (e.g., ITO or IZO).

As described above, in the TFT substrate 10 of the liquid crystal display device 100 according to the embodiment of the disclosure, the thickness t2a of the second layer L2 in the channel region 14a is equal to or more than 3.4% of the thickness tgi of the gate insulating layer 15. According to the investigation by the inventor of the present application, it has been found that when the insulating film to be the gate insulating layer 15 is patterned by etching, if the second layer L2 in the regions to be the source contact region 14b and the drain contact region 14c is entirely removed by etching (that is, the first layer L1 is exposed and the etching reaches the first layer L1), the source-drain breakdown voltage of the circuit TFT 3 decreases. Since the thickness t2a of the second layer L2 in the channel region 14a is equal to or more than 3.4% of the thickness tgi of the gate insulating layer 15 as in the embodiment of the disclosure, the second layer L2 in the regions to be the source contact region 14b and the drain contact region 14c can be more reliably left when the insulating film to be the gate insulating layer 15 is patterned, so that the source-drain breakdown voltage of the circuit TFT 3 can be sufficiently ensured.

The thickness t2a of the second layer L2 in the channel region 14a is not particularly limited as long as it is equal to or more than 3.4% of the thickness tgi of the gate insulating layer 15 (i.e., about 1/30 or more of the thickness tgi of the gate insulating layer 15), and is more preferably equal to or more than 6.7% of the thickness tgi of the gate insulating layer 15 (i.e., about 1/15 or more of the thickness tgi of the gate insulating layer 15). The thickness t2a of the second layer L2 in the channel region 14a is, for example, equal to or more than 5 nm.

Note that all of the plurality of circuit TFTs included in the gate driver 40 do not need to have the same structure as the exemplified circuit TFT 3. Among the plurality of circuit TFTs of the gate driver 40, a circuit TFT desired to have a high source-drain breakdown voltage may adopt the same structure as the exemplified circuit TFT 3.

### Effect of Third Layer

In a case in which a light blocking layer is disposed between the oxide semiconductor layer and the substrate of a TFT having a top gate structure or in a case in which the light blocking layer also functions as a lower gate electrode (i.e., in the case of a double gate structure), step disconnection of the oxide semiconductor layer caused by the light blocking layer being provided may occur. It is considered that such step disconnection can be suppressed by forming the oxide semiconductor layer to be relatively thick. However, since simply increasing the thickness of the oxide semiconductor layer is not enough, desired TFT characteristics may not be obtained and reliability may decrease due to a reason other than the step disconnection. For example, in a TFT including an oxide semiconductor layer of a single layer having a relatively high mobility as an active layer, when the oxide semiconductor layer is simply made thick, there is a possibility that a threshold voltage of the TFT shifts to a negative side because of deterioration (light degradation) due to backlight.

On the other hand, as illustrated, since the oxide semiconductor layer 14 includes the third layer L3 in addition to the first layer L1 and the second layer L2, a total thickness T of the oxide semiconductor layer 14 can be increased without increasing a thickness t1 of the first layer L1. Here, the total thickness T is the sum of the thickness t1 of the first layer L1 and a thickness t3 of the third layer L3 and the thickness t2a of the second layer L2 in the channel region 14a. The step disconnection of the oxide semiconductor layer 14 can be suppressed by increasing the total thickness T of the oxide semiconductor layer 14. Further, since the thickness t1 of the first layer L1 does not need to be significantly increased, a negative shift of the threshold voltage due to light degradation of the first layer L1 can be suppressed. Furthermore, since the first layer L1 is located closer to the gate insulating layer 15 side than the third layer L3, a decrease in mobility due to the third layer L3 being provided can be suppressed.

### Thickness of Oxide Semiconductor Layer

From the viewpoint of suppressing the step disconnection of the oxide semiconductor layer 14 caused by the light blocking layer 12, the total thickness T of the oxide semiconductor layer 14 is preferably equal to or more than 30 nm, and more preferably equal to or more than 40 nm. Further, from the viewpoint of reducing the step generated in the upper insulating layer 19, the total thickness T of the oxide semiconductor layer 14 is preferably equal to or less than 80 nm.

The thickness t1 of the first layer L1 is, for example, equal to or more than 4 nm and equal to or less than 12 nm. When the thickness t1 of the first layer L1 is equal to or more than 4 nm, a current path in the first layer L1 can be more reliably ensured, and thus an on-state current can be more effectively increased. When the thickness t1 of the first layer L1 is equal to or less than 12 nm, a negative shift of a threshold voltage due to light degradation can be more effectively suppressed.

As illustrated, when the oxide semiconductor layer 14 includes the third layer L3, from the view point of more effectively suppressing the negative shift of the threshold voltage due to the light degradation of the first layer L1 while ensuring the total thickness T of the oxide semiconductor layer 14, the thickness t1 of the first layer L1 is preferably equal to or less than ½ of the thickness t3 of the third layer L3, and more preferably equal to or less than ⅓ of the thickness t3 of the third layer L3. From the viewpoint of ensuring a current path in the first layer L1, the thickness t1 of the first layer L1 is preferably equal to or more than 1/7 of the thickness t3 of the third layer L3.

As described above, the thickness t2a of the second layer L2 in the channel region 14a is equal to or more than 3.4% of the thickness tgi of the gate insulating layer 15, and more preferably equal to or more than 6.7%. In addition, from the viewpoint of suppressing the decrease in the on-state current due to the second layer L2 being arranged on the gate insulating layer 15 side of the first layer L1, the thickness t2a of the second layer L2 in the channel region 14a is preferably equal to or less than 3/2 of the thickness t1 of the first layer L1, and is preferably equal to or less than ⅓ of the thickness t3 of the third layer L3.

From the viewpoint of suppressing the step disconnection of the oxide semiconductor layer 14 caused by the light blocking layer 12, the thickness t3 of the third layer L3 is preferably greater than each of the thickness t1 of the first layer L1 and the thickness t2a of the second layer L2 in the channel region 14a. The thickness t3 of the third layer L3 can be set such that the total thickness T of the oxide semiconductor layer 14 has a desired value. The thickness t3 of the third layer L3 is, for example, equal to or more than 6 nm and equal to or less than 50 nm. From the viewpoint of suppressing the step disconnection of the oxide semiconductor layer 14, the thickness t3 of the third layer L3 is preferably equal to or more than 6 nm. From the viewpoint of increasing the on-state current when the light blocking layer 12 is caused to function as the lower gate electrode, the thickness t3 of the third layer L3 is preferably equal to or less than 50 nm.

### Structure of Source Contact Hole and Drain Contact Hole

In the example illustrated in FIG. 4, the first layer L1 and the second layer L2 of the oxide semiconductor layer 14 are removed in the source contact hole CHs and the drain contact hole CHd. That is, each of the source contact hole CHs and the drain contact hole CHd is formed over the upper insulating layer 19, and the second layer L2 and the first layer L1 of the oxide semiconductor layer 14. This structure is obtained by, for example, removing the second layer L2 and the first layer L1 of the oxide semiconductor layer 14 when performing etching on the upper insulating layer 19.

The source electrode 17 is in contact with portions of the first layer L1 and the second layer L2 of the oxide semiconductor layer 14 exposed at the side surface of the source contact hole CHs and a portion of the third layer L3 exposed at the bottom surface of the source contact hole CHs. The drain electrode 18 is in contact with portions of the first layer L1 and the second layer L2 of the oxide semiconductor layer 14 exposed at the side surface of the drain contact hole CHd and a portion of the third layer L3 exposed at the bottom surface of the drain contact hole CHd. With such a structure, by increasing a contact area between the source electrode 17 and/or the drain electrode 18 and the oxide semiconductor layer 14, and bringing the source electrode 17 and/or the drain electrode 18 into direct contact with the first layer L1, contact resistance can be more effectively reduced.

Note that the structure of the source contact hole CHs and the drain contact hole CHd is not limited to the structure illustrated in FIG. 4. Since the second layer L2 of the oxide semiconductor layer 14 is removed in a part of the source contact region 14b and a part of the drain contact region 14c, and the source electrode 17 and the drain electrode 18 are in direct contact with the first layer L1 of the oxide semiconductor layer 14, the above-described effect can be obtained. For example, the first layer L1 of the oxide semiconductor layer 14 may be exposed at the bottom surface of each of the source contact hole CHs and the drain contact hole CHd.

The second layer L2 of the oxide semiconductor layer 14 may be present at least in a region of the source contact region 14b not overlapping the source contact hole CHs and may be present at least in a region of the drain contact region 14c not overlapping the drain contact hole CHd.

### Composition of Each Layer of Oxide Semiconductor Layer

In the TFT substrate 10 of the liquid crystal display device 100 according to the embodiment of the disclosure, the compositions of the first layer L1, the second layer L2, and the third layer L3 of the oxide semiconductor layer 14 are set so that the first layer L1 can have a higher mobility than the second layer L2 and the third layer L3.

The second layer L2 and the third layer L3 may include In, Ga, and Zn. For example, the second layer L2 and the third layer L3 can mainly include an In—Ga—Zn—O-based semiconductor. The compositions of the second layer L2 and the third layer L3 may be the same, or may be different from each other.

The first layer L1 may mainly include an In—Zn—O-based semiconductor layer. Alternatively, the first layer L1 may mainly include an oxide semiconductor including Sn. Examples of the oxide semiconductor including Sn include an In—Ga—Zn—Sn—O-based semiconductor, an In—Ga—Sn—O-based semiconductor, an In—Sn—Zn—O-based semiconductor, and the like.

When the second layer L2 and the third layer L3 mainly include the In—Ga—Zn—O-based semiconductor, and the first layer L1 mainly includes the In—Zn—O-based semiconductor, a ratio of In in the In—Ga—Zn—O-based semiconductor of each of the second layer L2 and the third layer L3 may be, for example, equal to or more than ⅓. The ratio (atomic number ratio) of In, Ga, and Zn in the In—Ga—Zn—O-based semiconductor of each of the second layer L2 and the third layer L3 may be, for example, 1:1:1, 4:2:4, and the like.

When the second layer L2 and the third layer L3 mainly include the In—Ga—Zn—O-based semiconductor, and the first layer L1 mainly includes the oxide semiconductor including Sn, the composition of the In—Ga—Zn—O-based semiconductor in the second layer L2 and the third layer L3 is not particularly limited. A ratio of In, Ga, and Zn in the second layer L2 and the third layer L3 may be, for example, 1:1:1, 4:2:4, 1:3:2, 1:3:6, and the like.

Here, In is referred to as a “first metal element”, and Ga and Zn are each referred to as a “second metal element”. It is known that mobility tends to increase with a higher ratio of the first metal element in the oxide semiconductor, whereas the mobility tends to decrease and crystallinity tends to increase with a higher ratio of the second metal element. Therefore, when the oxide semiconductor includes the first metal element and at least one second metal element (Ga or Zn), an oxide semiconductor layer having a desired mobility can be formed by adjusting a ratio of the metal elements.

An atomic number ratio of In to all metal elements included in the first layer L1 may be greater than an atomic number ratio of In to all metal elements included in the second layer L2 and the third layer L3. As an example, an atomic number ratio of the first metal element to all the metal elements included in the first layer L1 may be equal to or more than an atomic number ratio of the second metal element. Preferably, the atomic number ratio of the first metal element may be greater than the atomic number ratio of the second metal element. On the other hand, an atomic number ratio of the first metal element to all the metal elements included in the second layer L2 and the third layer L3 may be equal to or less than an atomic number ratio of the second metal element.

The first layer L1, the second layer L2, and the third layer L3 have the compositions described above, and thus the first layer L1 has the mobility higher than that of the second layer L2 and the third layer L3, and can function as a channel layer. Meanwhile, the second layer L2 and the third layer L3 are highly crystallized layers having crystallinity higher than that of the first layer L1, and have excellent etching resistance and barrier properties. Therefore, for example, in a patterning process of the gate insulating layer 15 and the gate electrode 16, the second layer L2 can function as a protection layer and a sacrificing layer of the first layer L1.

Note that the first layer L1, and the second layer L2 and the third layer L3 may have the same composition. Even in this case, the mobility of the first layer L1 can be set higher than that of the second layer L2 and the third layer L3 by setting different formation conditions and crystal structures of each oxide semiconductor layer, for example.

### Manufacturing Method of TFT Substrate

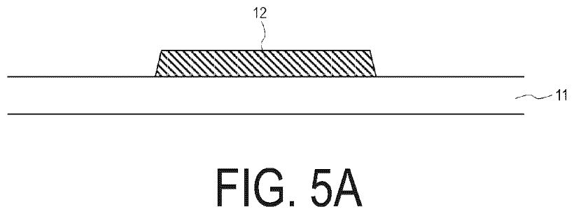

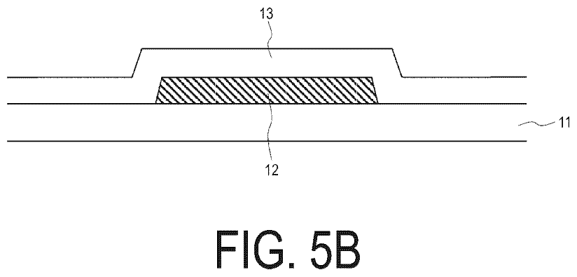

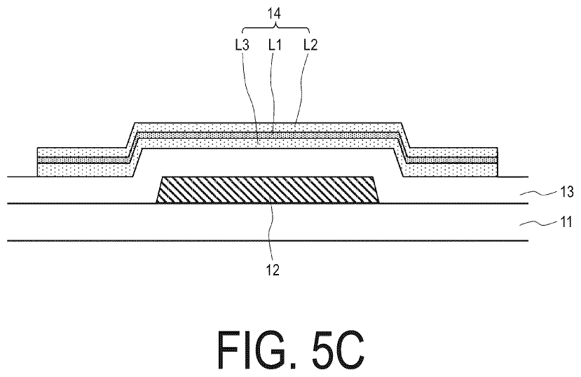

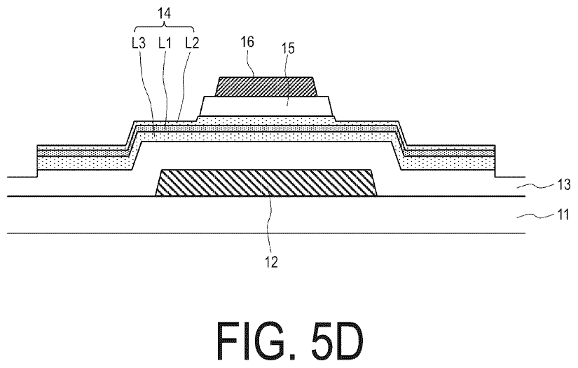

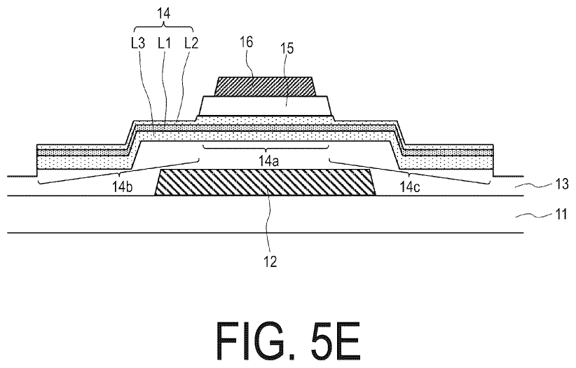

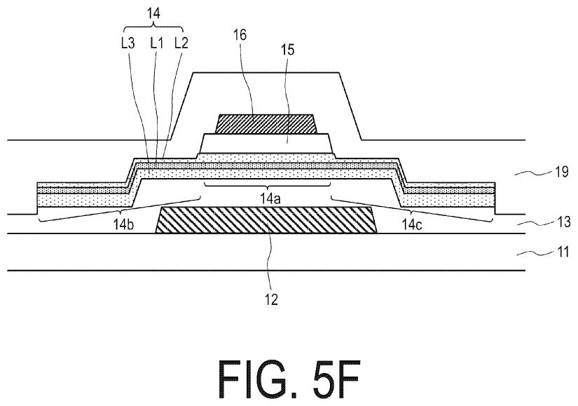

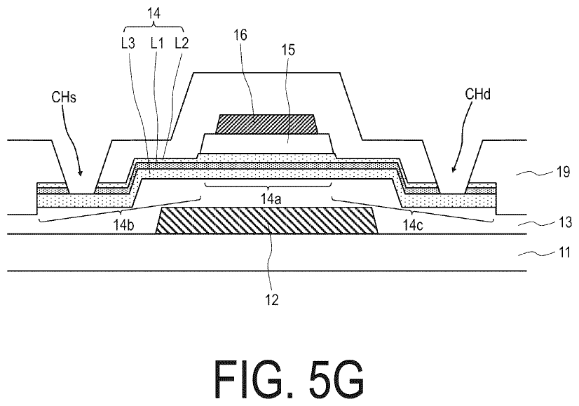

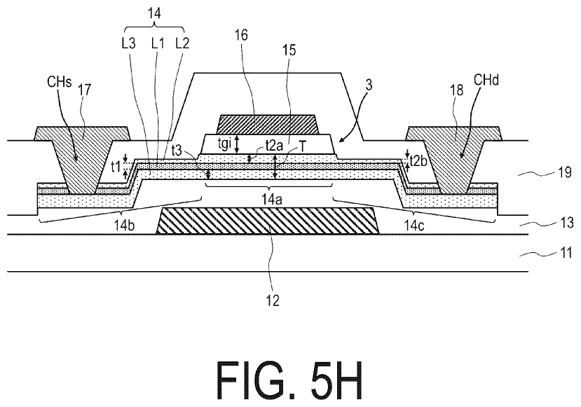

A description is given of a manufacturing method of the TFT substrate 10 with reference to FIG. 5A to FIG. 5H. FIG. 5A to FIG. 5H are process cross-sectional views for illustrating a manufacturing method of the TFT substrate 10.

First, as illustrated in FIG. 5A, the light blocking layer 12 is formed on the substrate 11. Specifically, the light blocking layer 12 can be formed by forming a conductive film (thickness of, for example, 50 nm or more and 500 nm or less) for the light blocking layer on the substrate 11 having insulating properties by a sputtering method or the like, and then patterning the conductive film for the light blocking layer.

A glass substrate, a plastic substrate (resin substrate) having heat resistance, or the like can be used as the substrate 11, for example.

As the conductive film for the light blocking layer, for example, a metal film including an element selected from aluminum (Al), chromium (Cr), copper (Cu), tantalum (Ta), titanium (Ti), molybdenum (Mo), or tungsten (W), or an alloy film including these elements as components can be used. A layered film including a plurality of films of these films may be used. For example, a layered film having a triple-layer structure of titanium film-aluminum film-titanium film, or a triple-layer structure of molybdenum film-aluminum film-molybdenum film can be used. Note that the conductive film for the light blocking layer is not limited to the triple-layer structure, and may have a single-layer, a dual-layer structure, or a layered structure of four or more layers. Here, a layered film having a lower layer of a Ti film (thickness of 15 nm or more and 70 nm or less) and an upper layer of a Cu film (thickness of 200 nm or more and 400 nm or less) is used as the conductive film for the light blocking layer.

Next, as illustrated in FIG. 5B, the lower insulating layer 13 that covers the light blocking layer 12 is formed. The lower insulating layer 13 is formed by CVD, for example. The thickness of the lower insulating layer 13 is, for example, equal to or more than 150 nm and equal to or less than 550 nm. When the thickness of the lower insulating layer 13 is equal to or more than 150 nm, the step disconnection of the oxide semiconductor layer 14 generated due to the light blocking layer 12 can be more effectively reduced. When the thickness of the lower insulating layer 13 is equal to or less than 550 nm, the on-state current can be more effectively increased in a case in which the light blocking layer 12 is caused to function as a lower gate electrode.

As the lower insulating layer 13, a silicon oxide (SiO₂) layer, a silicon nitride (SiNx) layer, a silicon oxynitride (SiOxNy; x>y) layer, a silicon nitride oxide (SiNxOy; x>y) layer, or the like can be used as appropriate. The lower insulating layer 13 may have a layered structure. For example, a silicon nitride layer, a silicon nitride oxide layer, or the like may be formed on the substrate 11 side (lower layer) in order to prevent diffusion of impurities and the like from the substrate 11, and a silicon oxide layer, a silicon oxynitride layer, or the like may be formed on a layer (upper layer) on top of the substrate 11 side layer in order to ensure insulating properties. Here, a layered film having a lower layer of a silicon nitride layer (thickness of 100 nm or more and 500 nm or less) and an upper layer of a silicon oxide layer (thickness of 20 nm or more and 300 nm or less) is used. In this way, when an insulating layer that contains oxygen is used as the uppermost layer of the lower insulating layer 13 (in other words, the layer that is in contact with the oxide semiconductor layer 14), in a case in which the oxygen deficiency occurs in the oxide semiconductor layer 14, since the oxygen deficiency can be recovered, the oxygen deficiency of the oxide semiconductor layer 14 can be reduced.

Subsequently, as illustrated in FIG. 5C, the oxide semiconductor layer 14 having a layered structure is formed on the lower insulating layer 13. Specifically, first, a lower oxide semiconductor film, a middle oxide semiconductor film, and an upper oxide semiconductor film are formed from the lower insulating layer 13 side using a sputtering method to thereby form a layered film. Each of the oxide semiconductor films has a composition and a thickness corresponding to the third layer L3, the first layer L1, and the second layer L2. Here, the thickness of the upper oxide semiconductor film corresponding to the second layer L2 is equal to or more than 3.4% of the thickness tgi of the gate insulating layer 15 to be formed later. Each of the oxide semiconductor films may be a crystalline oxide semiconductor film, or may be an amorphous oxide semiconductor film. Annealing process may be performed on the layered film. Here, heat treatment is performed at a temperature of equal to or higher than 200° C. and equal to or lower than 500° C. in an air atmosphere. The heat treatment time is, for example, equal to or longer than 30 minutes and equal to or less than 2 hours. Thereafter, the layered film is patterned. The patterning of the layered film can be performed by, for example, wet etching using a PAN-based etching solution containing phosphoric acid, nitric acid, and acetic acid, or an oxalic acid-based etching solution. Thus, the oxide semiconductor layer 14 including the third layer L3, the first layer L1, and the second layer L2 in this order from the lower insulating layer 13 side is obtained.

Next, as illustrated in FIG. 5D, the gate insulating layer 15 and the gate electrode 16 are formed on a part of the oxide semiconductor layer 14. Specifically, first, an insulating film and a gate conductive film are formed in this order to cover the oxide semiconductor layer 14.

As the insulating film, an insulating film similar to the lower insulating layer 13 (the insulating film exemplified as the lower insulating layer 13) can be used. Here, as the insulating film, a silicon oxide (SiO₂) film is formed by CVD, for example. When an oxide film such as a silicon oxide film is used as the insulating film, oxidation deficits generated in the channel region 14a of the oxide semiconductor layer 14 can be reduced by the oxide film, and thus, the channel region 14a being low-resistive can be suppressed. The thickness of the insulating film (i.e., the thickness of the gate insulating layer 15) may be, for example, equal to or more than 80 nm and equal to or less than 250 nm, and preferably equal to or more than 100 nm and equal to or less than 200 nm. By reducing the thickness of the gate insulating layer 15 (for example, to be equal to or less than 200 nm), a decrease in the on-state current due to the second layer L2 being disposed on the first layer L1 can be compensated, and thus a high on-state current can be maintained. When the thickness of the gate insulating layer 15 is equal to or more than 100 nm, reliability can be improved.

A conductive film similar to the conductive film for the light blocking layer can be used as the gate conductive film. As the gate conductive film, a Cu/Ti layered film having a Ti film as a lower layer and a Cu film as an upper layer, or a Cu/Mo layered film having a Mo film as a lower layer and a Cu film as an upper layer may be used. The thickness of the gate conductive film is, for example, equal to or more than 50 nm and equal to or less than 500 nm.

Next, the gate conductive film is patterned by a photolithography process. Here, a resist layer is formed on the gate conductive film. Etching (for example, wet etching) of the gate conductive film is performed by using the resist layer as a mask to thereby form the gate electrode 16.

Thereafter, the gate insulating layer 15 is formed by etching the insulating film using the resist layer or the gate electrode 16 as a mask. As described above, a part of the second layer L2 of the oxide semiconductor layer 14 may be etched when patterning of the insulating film to be the gate insulating layer 15 is performed.

Subsequently, resistance reduction processing of the oxide semiconductor layer 14 is performed. The resistance reduction processing is, for example, plasma processing. Thus, as illustrated in FIG. 5E, regions of the oxide semiconductor layer 14 not overlapping the gate electrode 16 and the gate insulating layer 15 (exposed regions) are low resistance regions (the source contact region 14b and the drain contact region 14c) having a lower specific resistance than a region (the channel region 14a) overlapping the gate electrode 16 and the gate insulating layer 15. Note that the method of the resistance reduction processing is not limited to the processing exemplified here.

Subsequently, as illustrated in FIG. 5F, the upper insulating layer 19 that covers the oxide semiconductor layer 14, the gate insulating layer 15, and the gate electrode 16 is formed. The upper insulating layer 19 can be formed, for example, by CVD. The thickness of the upper insulating layer 19 is, for example, equal to or more than 100 nm and equal to or less than 500 nm. As the upper insulating layer 19, a silicon oxide layer, a silicon nitride layer, a silicon oxynitride layer, or a silicon nitride oxide layer can be used. As the upper insulating layer 19, an insulating layer that reduces an oxide semiconductor, such as a silicon nitride layer is used, the specific resistance of the region, of the oxide semiconductor layer 14, that is in contact with the upper insulating layer 19 can be maintained to be low.

Subsequently, as illustrated in FIG. 5G, the source contact hole CHs and the drain contact hole CHd are formed in the upper insulating layer 19. The source contact hole CHs and the drain contact hole CHd can be formed by, in particular, the photolithography process and the etching. The etching may be dry etching, for example. In the example illustrated, during the etching, portions of the second layer L2 and the first layer L1 of the oxide semiconductor layer 14 located in the source contact hole CHs and the drain contact hole CHd are also removed, and the third layer L3 of the oxide semiconductor layer 14 is exposed at the bottom surfaces of the source contact hole CHs and the drain contact hole CHd.

Next, as illustrated in FIG. 5H, the source electrode 17 is formed on the upper insulating layer 19 and in the source contact hole CHs, and the drain electrode 18 is formed on the upper insulating layer 19 and in the drain contact hole CHd. Specifically, the source electrode 17 and the drain electrode 18 can be formed by forming a source conductive film (thickness of, for example, 50 nm or more and 500 nm or less) on the upper insulating layer 19, in the source contact hole CHs and in the drain contact hole CHd, and then patterning the source conductive film. The patterning of the source conductive film can be performed, for example, by dry etching or wet etching. As the source conductive film, an element selected from aluminum (Al), chromium (Cr), copper (Cu), tantalum (Ta), titanium (Ti), molybdenum (Mo), and tungsten (W), or an alloy including these elements as components can be used, for example. For example, the source conductive film may have a triple-layer structure of titanium film-aluminum film-titanium film, or a triple-layer structure of molybdenum film-aluminum film-molybdenum film. Note that the source conductive film is not limited to the triple-layer structure, and may have a single-layer structure or a dual-layer structure, or a layered structure of four or more layers. Here, a layered film having a lower layer of a Ti film (thickness of 15 nm or more and 70 nm or less) and an upper layer of a Cu film (thickness of 200 nm or more and 400 nm or less) is used.

Thereafter, an interlayer insulating layer covering the circuit TFT 3 and the pixel TFT 2, the pixel electrode PE, and the like are formed, thereby obtaining the TFT substrate 10.

In the above-described manufacturing method, the second layer L2 is formed so as to have the thickness that is equal to or more than 3.4% of the gate insulating layer 15 in the step of forming the oxide semiconductor layer 14. That is, the thickness of the second layer L2 is set such that the second layer L2 remains over the entire source contact region 14b and the entire drain contact region 14c at the completion of the step of forming the gate insulating layer 15 by etching the insulating film. Therefore, the source-drain breakdown voltage of the circuit TFT 3 can be sufficiently ensured.

### Other Configuration of TFT Substrate

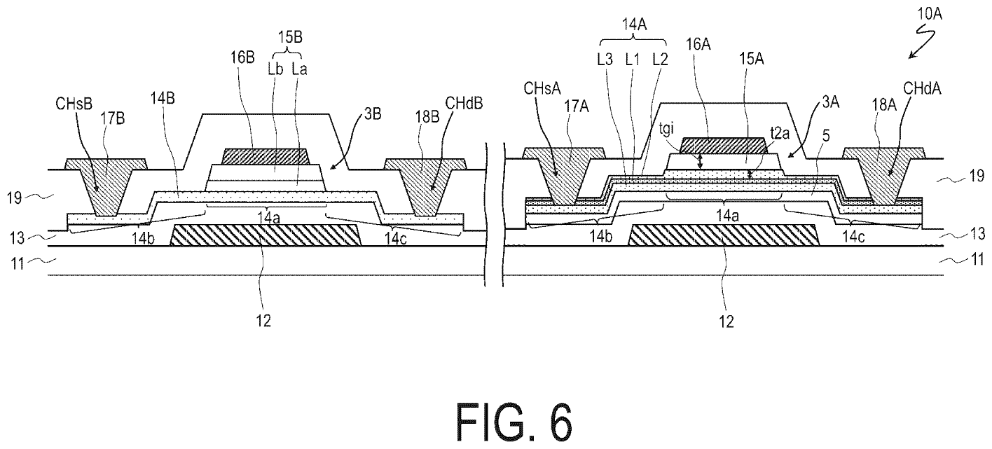

Another TFT substrate 10A used in the liquid crystal display device 100 according to the embodiment of the disclosure will be described with reference to FIG. 6. FIG. 6 is a cross-sectional view schematically illustrating the TFT substrate 10A, and illustrates a region corresponding to two circuit TFTs 3A and 3B of the circuit TFTs included in the gate driver 40. The following description of the TFT substrate 10A mainly describes differences from the TFT substrate 10 illustrated in FIG. 4.

As illustrated in FIG. 6, the TFT substrate 10A includes the circuit TFTs 3A and 3B having different structures from each other. Hereinafter, the circuit TFT 3A illustrated on the right side in FIG. 6 is referred to as a “first circuit TFT”, and the circuit TFT 3B illustrated on the left side in FIG. 6 is referred to as a “second circuit TFT”. Although one first circuit TFT 3A and one second circuit TFT 3B are illustrated here, the TFT substrate 10A has a plurality of first circuit TFTs 3A having the structure illustrated in FIG. 6 and a plurality of second circuit TFTs 3B having the structure illustrated in FIG. 6.

The first circuit TFT 3A has substantially the same structure as the circuit TFT 3 illustrated in FIG. 4. The first circuit TFT 3A includes a first oxide semiconductor layer 14A, a first gate insulating layer 15A, a first gate electrode 16A, a first source electrode 17A, and a first drain electrode 18A, which correspond to the oxide semiconductor layer 14, the gate insulating layer 15, the gate electrode 16, the source electrode 17, and the drain electrode 18 in the circuit TFT 3 illustrated in FIG. 4. However, an insulating layer 5 different from the lower insulating layer 13 is interposed between the first oxide semiconductor layer 14A of the first circuit TFT 3A and the lower insulating layer 13, and the first oxide semiconductor layer 14A is formed on the insulating layer 5.

Similar to the oxide semiconductor layer 14 of the circuit TFT 3, the first oxide semiconductor layer 14A of the first circuit TFT 3A has a layered structure including the first layer L1, the second layer L2, and the third layer L3. The thickness t2a of the second layer L2 in the channel region 14a is equal to or more than 3.4% of the thickness tgi of the gate insulating layer 15.

The first source electrode 17A and the first drain electrode 18A of the first circuit TFT 3A are respectively connected to the source contact region 14b and the drain contact region 14c of the first oxide semiconductor layer 14A in a first source contact hole CHsA and a first drain contact hole CHdA formed in the upper insulating layer 19.

The second circuit TFT 3B includes a second oxide semiconductor layer 14B provided on the lower insulating layer 13, a second gate insulating layer 15B provided on the second oxide semiconductor layer 14B, and a second gate electrode 16B arranged to face the second oxide semiconductor layer 14B with the second gate insulating layer 15B interposed therebetween. The second circuit TFT 3B further includes a second source electrode 17B and a second drain electrode 18B each electrically connected to the second oxide semiconductor layer 14B.

The second oxide semiconductor layer 14B is formed in a layer different from the first oxide semiconductor layer 14A of the first circuit TFT 3A, and has a lower mobility than the first layer L1 of the first oxide semiconductor layer 14A. In the example illustrated, the second oxide semiconductor layer 14B does not have a layered structure and is a single layer.

The second gate insulating layer 15B is formed on the second oxide semiconductor layer 14B, and overlaps the channel region 14a of the second oxide semiconductor layer 14B in a plan view. That is, the second gate insulating layer 15B is removed on the source contact region 14b and the drain contact region 14c of the second oxide semiconductor layer 14B.

The second gate insulating layer 15B has a layered structure. To be specific, the second gate insulating layer 15B includes a lower layer La and an upper layer Lb disposed on the lower layer La. The lower layer La is formed in the same layer as the insulating layer 5 located between the first oxide semiconductor layer 14A of the first circuit TFT 3A and the lower insulating layer 13. The upper layer Lb is formed in the same layer as the first gate insulating layer 15A of the first circuit TFT 3A.

The second gate electrode 16B is disposed on the channel region 14a of the second oxide semiconductor layer 14B with the second gate insulating layer 15B interposed therebetween.

The second source electrode 17B and the second drain electrode 18B are formed on the upper insulating layer 19. The second source electrode 17B is electrically connected to the source contact region 14b of the second oxide semiconductor layer 14B, and the second drain electrode 18B is electrically connected to the drain contact region 14c of the second oxide semiconductor layer 14B. The second source electrode 17B is connected to the source contact region 14b in a second source contact hole CHsB formed in the upper insulating layer 19, and the second drain electrode 18B is connected to the drain contact region 14c in a second drain contact hole CHdB formed in the upper insulating layer 19.

As described above, the first circuit TFT 3A and the second circuit TFT 3B are mixed in the TFT substrate 10A. Since the second oxide semiconductor layer 14B of the second circuit TFT 3B has a lower mobility than the first layer L1 of the first oxide semiconductor layer 14A of the first circuit TFT 3A, it is easy for the second circuit TFT 3B to ensure a higher source-drain breakdown voltage than the first circuit TFT 3A. The size of the gate driver 40 can be reduced while ensuring the reliability of the gate driver 40 by using the second circuit TFT 3B for a circuit TFT for which a particularly high source-drain breakdown voltage is desired and using the first circuit TFT 3A for a circuit TFT for which the source-drain breakdown voltage may be slightly lower, among the plurality of circuit TFTs of the gate driver 40.

The composition of the second oxide semiconductor layer 14B of the second circuit TFT 3B is not particularly limited as long as the second oxide semiconductor layer 14B has a mobility lower than that of the first layer L1 of the first oxide semiconductor layer 14A. From the viewpoint of suppressing the step disconnection of the second oxide semiconductor layer 14B caused by the light blocking layer 12, the thickness of the second oxide semiconductor layer 14B is preferably equal to or more than 30 nm, and more preferably equal to or more than 40 nm. In addition, from the viewpoint of reducing the step generated in the upper insulating layer 19, the thickness of the second oxide semiconductor layer 14B is preferably equal to or less than 80 nm.

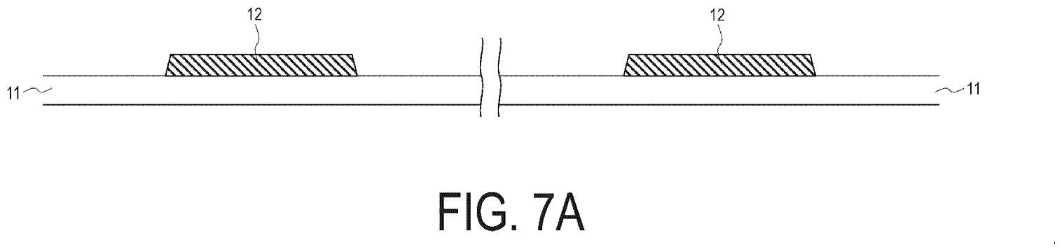

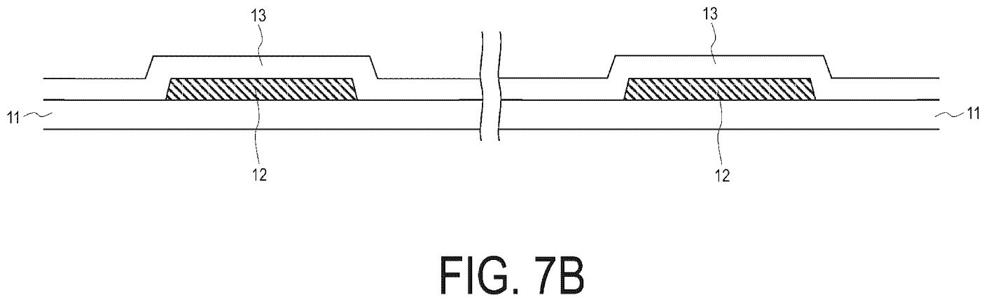

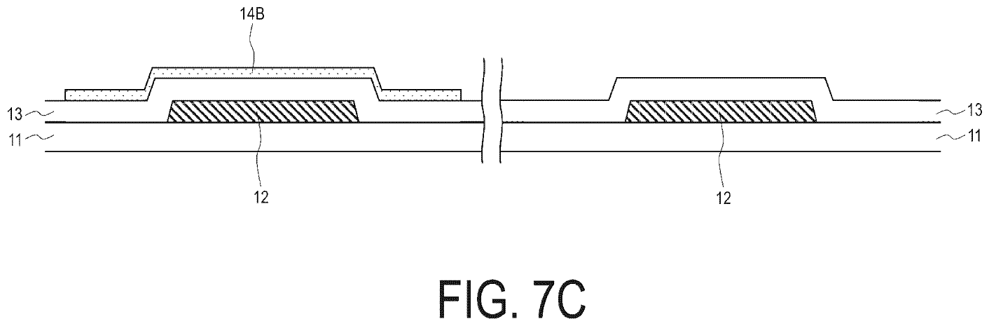

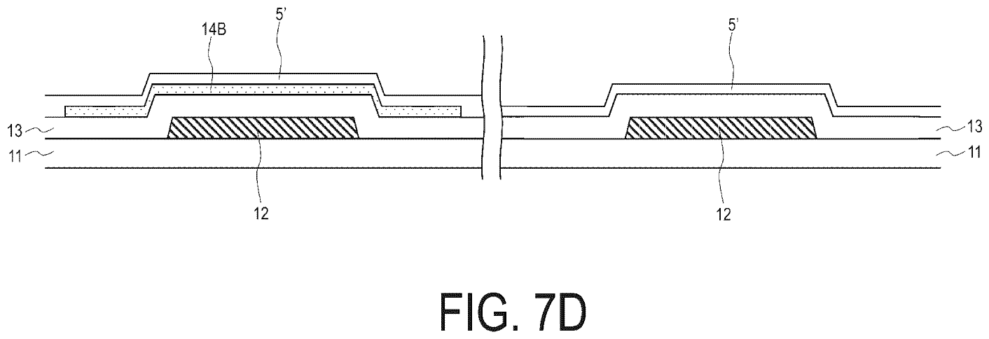

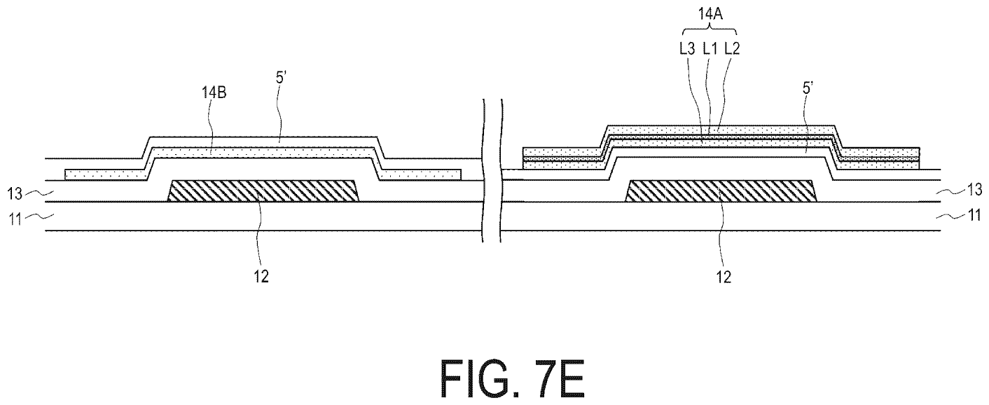

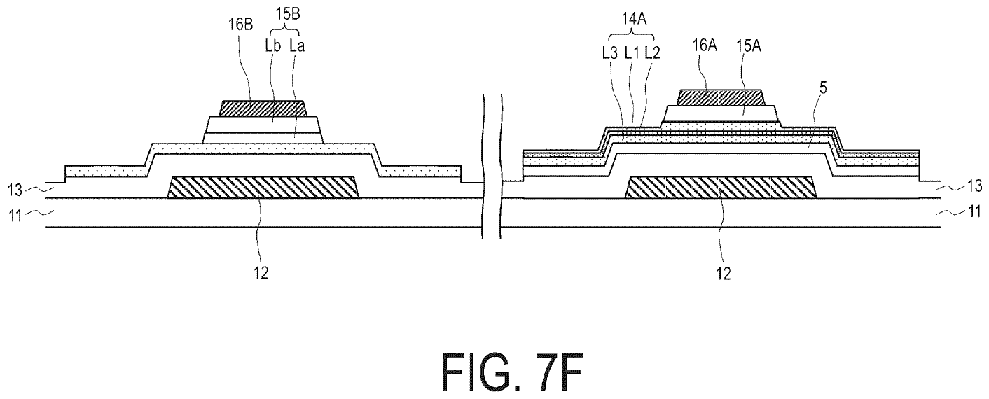

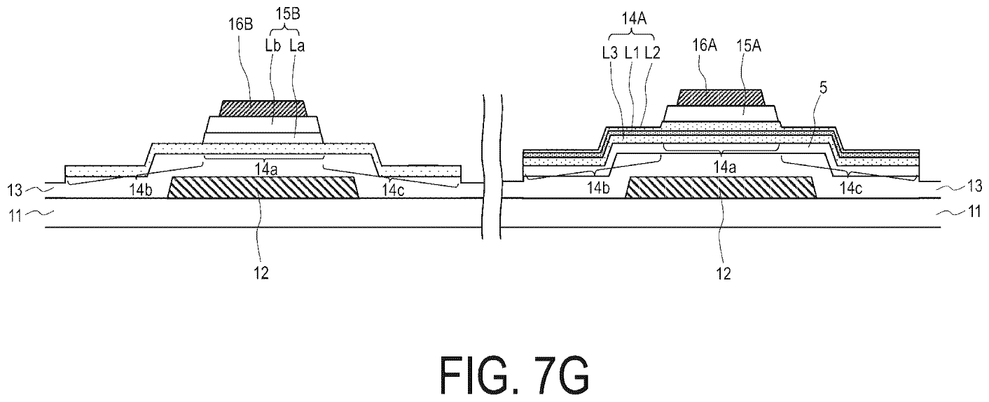

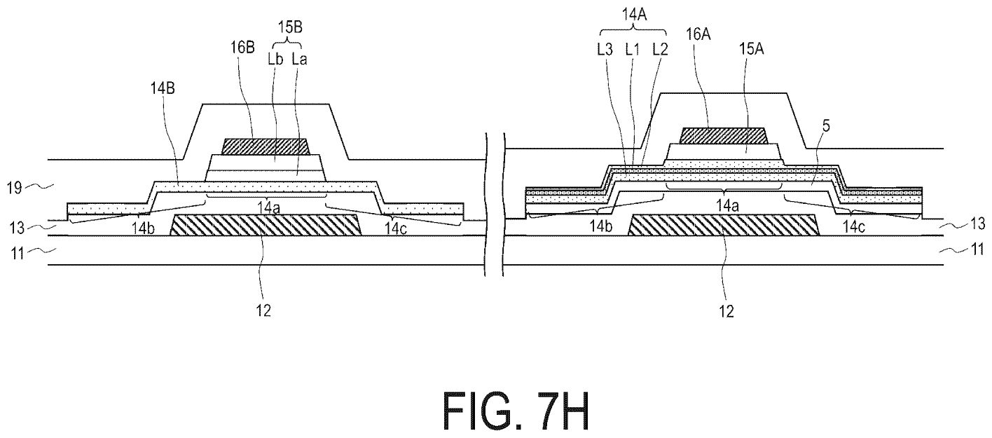

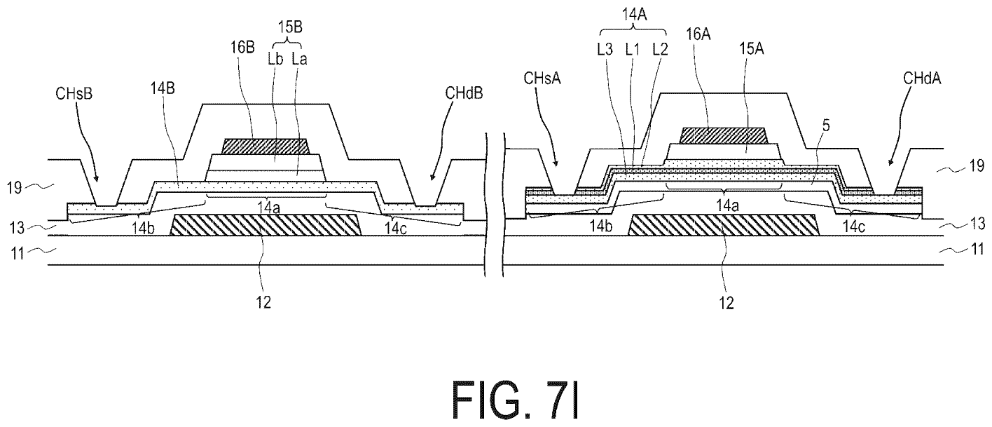

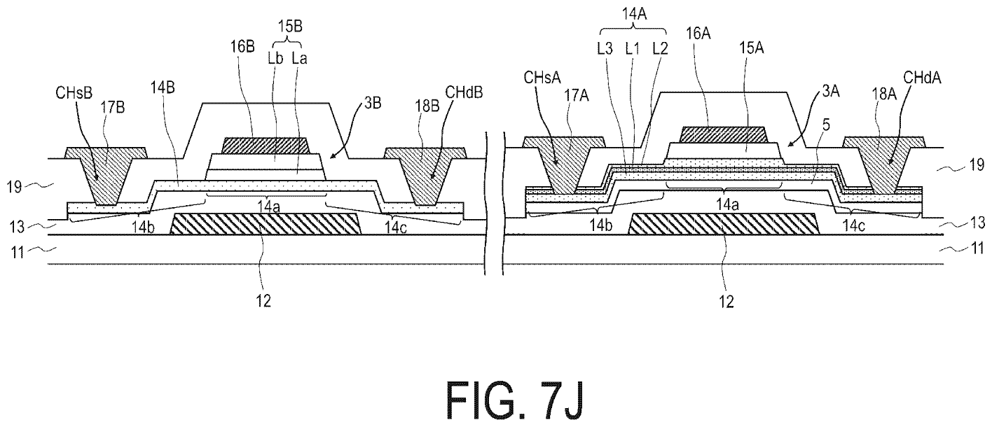

A description is given of a manufacturing method of the TFT substrate 10A with reference to FIG. 7A to FIG. 7J. FIG. 7A to FIG. 7J are process cross-sectional views for illustrating a manufacturing method of the TFT substrate 10A.

First, as illustrated in FIG. 7A, the light blocking layer 12 is formed on the substrate 11. Specifically, the light blocking layer 12 can be formed by forming a conductive film for the light blocking layer on the substrate 11 having insulating properties by a sputtering method or the like, and then patterning the conductive film for the light blocking layer.

Next, as illustrated in FIG. 7B, the lower insulating layer 13 that covers the light blocking layer 12 is formed. The lower insulating layer 13 is formed by CVD, for example.

Subsequently, as illustrated in FIG. 7C, the second oxide semiconductor layer 14B is formed on the lower insulating layer 13. Specifically, first, the second oxide semiconductor layer 14B can be formed by forming an oxide semiconductor film by using a sputtering method and then patterning the oxide semiconductor film.

Next, as illustrated in FIG. 7D, the insulating film 5′ that covers the second oxide semiconductor layer 14B is deposited. This insulating film 5′ is patterned later to become the insulating layer 5 and the lower layer La of the second gate insulating layer 15B. The lower insulating layer 13 is formed by CVD, for example. As the insulating film 5′, an insulating film similar to the lower insulating layer 13 can be used.

Subsequently, as illustrated in FIG. 7E, the first oxide semiconductor layer 14A having a layered structure is formed on the insulating film 5′. Specifically, first, a layered film can be formed by forming a lower oxide semiconductor film, a middle oxide semiconductor film, and an upper oxide semiconductor film from the insulating film 5′ side using a sputtering method and then the first oxide semiconductor layer 14A can be formed by patterning the layered film.

Next, as illustrated in FIG. 7F, the first gate insulating layer 15A and the first gate electrode 16A are formed on a part of the first oxide semiconductor layer 14A, and the second gate insulating layer 15B and the second gate electrode 16B are formed on a part of the second oxide semiconductor layer 14B. Specifically, first, a further insulating film and a gate conductive film are formed in this order to cover the first oxide semiconductor layer 14A and the insulating film 5′.

Next, the gate conductive film is patterned by a photolithography process. Here, a resist layer is formed on the gate conductive film, and etching (for example, wet etching) of the gate conductive film is performed using the resist layer as a mask, thereby forming the first gate electrode 16A and the second gate electrode 16B.

Then, using the resist layer or the first and second gate electrodes 16A and 16B as a mask, the further insulating film and the insulating film 5′ are etched to thereby form the first gate insulating layer 15A and the second gate insulating layer 15B including the lower layer La and the upper layer Lb. At this time, by patterning the insulating film 5′, a part thereof becomes the lower layer La of the second gate insulating layer 15B and another part thereof becomes the insulating layer 5.

Subsequently, the resistance reduction processing of the first oxide semiconductor layer 14A and the second oxide semiconductor layer 14B is performed. The resistance reduction processing is, for example, plasma processing. Thus, as illustrated in FIG. 7G, regions of the first oxide semiconductor layer 14A overlapping neither the first gate electrode 16A nor the first gate insulating layer 15A (exposed regions) are low resistance regions (the source contact region 14b and the drain contact region 14c) having a lower specific resistance than a region (the channel region 14a) overlapping the first gate electrode 16A and the first gate insulating layer 15A. Similarly, regions of the second oxide semiconductor layer 14B overlapping neither the second gate electrode 16B nor the second gate insulating layer 15B (exposed regions) are low resistance regions (the source contact region 14b and the drain contact region 14c) having a lower specific resistance than a region (the channel region 14a) overlapping the second gate electrode 16B and the second gate insulating layer 15B. Note that the method of the resistance reduction processing is not limited to the processing exemplified here.

Next, as illustrated in FIG. 7H, the upper insulating layer 19 that covers the first oxide semiconductor layer 14A, the second oxide semiconductor layer 14B, and the like is formed. The upper insulating layer 19 can be formed, for example, by CVD.

Subsequently, as illustrated in FIG. 7I, the first source contact hole CHsA, the first drain contact hole CHdA, a second source contact hole CHsB, and a second drain contact hole CHdB are formed in the upper insulating layer 19. Specifically, these layers can be formed by a photolithography process and etching. The etching may be dry etching, for example. In the example illustrated, during the etching, portions of the second layer L2 and the first layer L1 of the first oxide semiconductor layer 14A located in the first source contact hole CHsA and the first drain contact hole CHdA are also removed, and the third layer L3 of the first oxide semiconductor layer 14A is exposed at the bottom surfaces of the first source contact hole CHsA and the first drain contact hole CHdA.

Next, as illustrated in FIG. 7J, the first source electrode 17A is formed on the upper insulating layer 19 and in the first source contact hole CHsA, and the first drain electrode 18A is formed on the upper insulating layer 19 and in the first drain contact hole CHdA. Further, at this time, the second source electrode 17B is formed on the upper insulating layer 19 and in the second source contact hole CHsB, and the second drain electrode 18B is formed on the upper insulating layer 19 and in the second drain contact hole CHdB. To be specific, the first source electrode 17A, the first drain electrode 18A, the second source electrode 17B, and the second drain electrode 18B can be formed by forming a source conductive film on the upper insulating layer 19 and in the first source contact hole CHsA, the first drain contact hole CHdA, the second source contact hole CHsB, and the second drain contact hole CHdB and then patterning the source conductive film.

Thereafter, an interlayer insulating layer covering the first circuit TFT 3A, the second circuit TFT 3B, and the pixel TFT 2, the pixel electrode PE, and the like are formed, thereby obtaining the TFT substrate 10A.

### Still Other Configuration of TFT Substrate

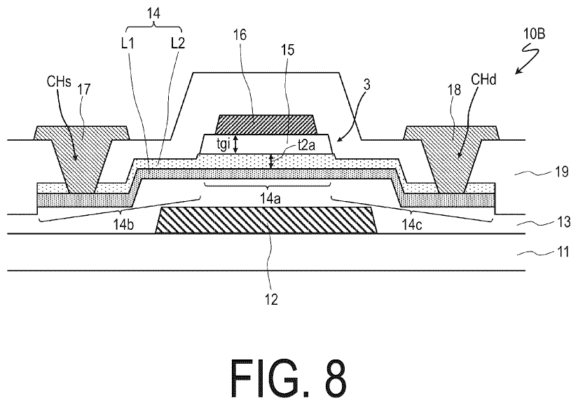

A still another TFT substrate 10B used for the liquid crystal display device 100 according to the embodiment of the disclosure will be described with reference to FIG. 8. FIG. 8 is a cross-sectional view schematically illustrating the TFT substrate 10B, and illustrates a region corresponding to a certain circuit TFT 3 of the circuit TFTs included in the gate driver 40. The following description of the TFT substrate 10B mainly describes differences from the TFT substrate 10 illustrated in FIG. 4.

As illustrated in FIG. 8, the TFT substrate 10B is different from the TFT substrate 10 illustrated in FIG. 4 in that the oxide semiconductor layer 14 of the circuit TFT 3 does not include the third layer L3. The oxide semiconductor layer 14 has a layered structure including the first layer L1 and the second layer L2, and the thickness t2a of the second layer L2 in the channel region 14a is equal to or more than 3.4% of the thickness tgi of the gate insulating layer 15. Therefore, the source-drain breakdown voltage of the circuit TFT 3 can be sufficiently ensured.

In the example illustrated in FIG. 8, the second layer L2 of the oxide semiconductor layer 14 is removed in the source contact hole CHs and the drain contact hole CHd. The source electrode 17 is in contact with a portion of the second layer L2 of the oxide semiconductor layer 14 exposed at the side surface of the source contact hole CHs and a portion of the first layer L1 exposed at the bottom surface of the source contact hole CHs. The drain electrode 18 is in contact with a portion of the second layer L2 of the oxide semiconductor layer 14 exposed at the side surface of the drain contact hole CHd and a portion of the first layer L1 exposed at the bottom surface of the drain contact hole CHd. With such a structure, by increasing a contact area between the source electrode 17 and/or the drain electrode 18, and the oxide semiconductor layer 14, and bringing the source electrode 17 and/or the drain electrode 18 into direct contact with the first layer L1, contact resistance can be more effectively reduced.

### Configuration of Gate Driver

A specific configuration of a gate driver is described. Although the gate driver may have various known configurations, here, the configuration disclosed in U.S. Patent Application Publication No. 2020/0135132 will be described as an example.

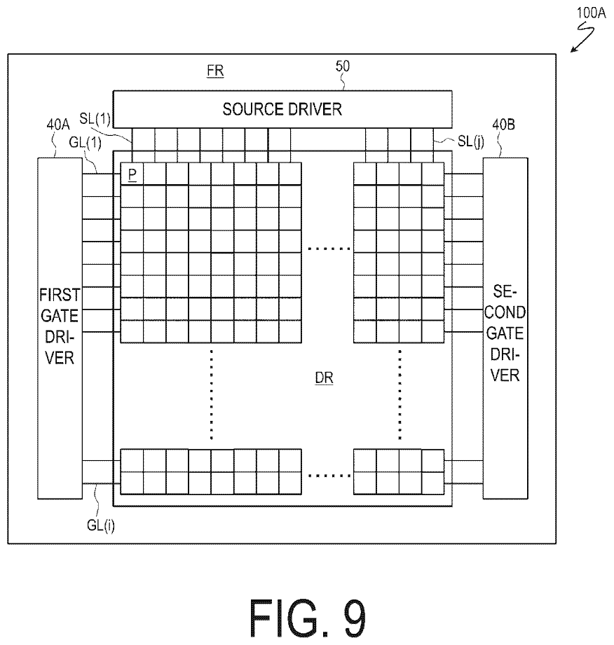

FIG. 9 is a schematic plan view schematically illustrating a liquid crystal display device 100A provided with a first gate driver 40A and a second gate driver 40B having a configuration disclosed in US Patent Application Publication No. 2020/0135132.

As illustrated in FIG. 9, the liquid crystal display device 100A includes the display region DR defined by the plurality of pixels P and the non-display region FR positioned in a periphery of the display region DR. In addition, the liquid crystal display device 100A includes a first gate driver 40A and a second gate driver 40B that drive the gate bus lines GL(1) to GL(i), and a source driver 50 that drives the source bus lines SL(1) to SL(j).

The first gate driver 40A, the second gate driver 40B, and the source driver 50 are arranged in the non-display region FR. The first gate driver 40A and the second gate driver 40B are GDM circuits. The first gate driver 40A is arranged on the left side of the display region DR, and the second gate driver 40B is arranged on the right side of the display region DR. That is, the first gate driver 40A and the second gate driver 40B are arranged on one end side and the other end side of the gate bus lines GL(1) to GL(i), respectively.

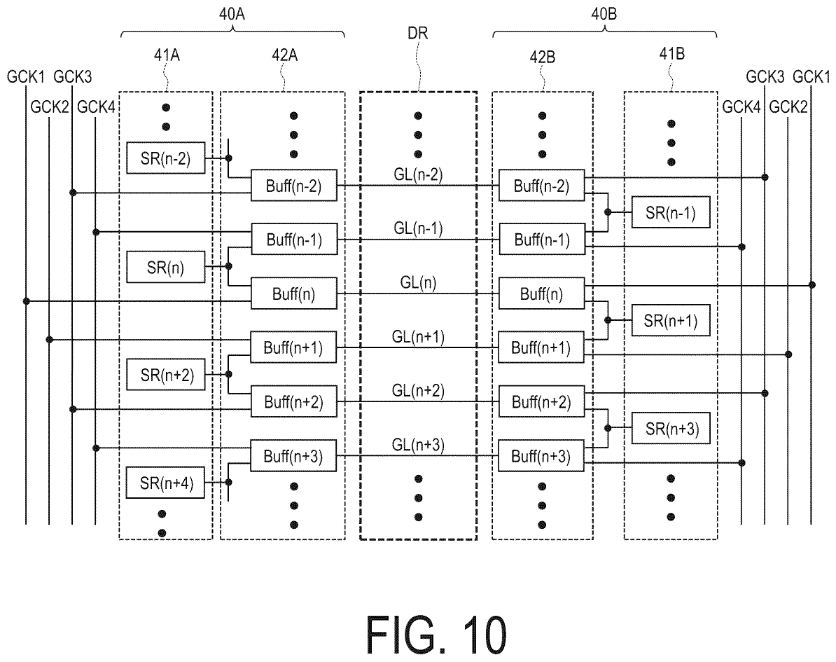

FIG. 10 is a diagram illustrating an overall configuration of the first gate driver 40A and the second gate driver 40B.

Each of the first gate driver 40A and the second gate driver 40B operates based on a four-phase clock signal including a first gate clock signal GCK1, a second gate clock signal GCK2, a third gate clock signal GCK3, and a fourth gate clock signal GCK4.

The first gate driver 40A includes a first shift register 41A and a first output buffer unit 42A. The first shift register 41A includes a plurality of cascade-connected bistable circuits SR (in FIG. 10, denoted by . . . SR(n−2), SR(n), SR(n+2), SR(n+4) . . . ). The first output buffer unit 42A includes a plurality of buffer circuits Buff (in FIG. 10, denoted by . . . Buff(n−2), Buff(n−1), Buff(n), Buff(n+1), Buff(n+2), Buff(n+3) . . . ).

The number of bistable circuits SR of the first shift register 41A is half the number i of pixel rows (i.e., i/2). On the other hand, the number of buffer circuits Buff of the first output buffer unit 42A is the same as the number i of pixel rows (i.e., i). Each of the bistable circuits SR of the first shift register 41A corresponds to two buffer circuits Buff, and controls the two buffer circuits Buff by supplying signals outputted therefrom to the two buffer circuits Buff.

The second gate driver 40B includes a second shift register 41B and a second output buffer unit 42B. The second shift register 41B includes a plurality of cascade-connected bistable circuits SR (in FIG. 10, denoted by . . . SR(n−1), SR(n+1), SR(n+3) . . . ). The second output buffer unit 42B includes a plurality of buffer circuits Buff (in FIG. 10, denoted by . . . Buff(n−2), Buff(n−1), Buff(n), Buff(n+1), Buff(n+2), Buff(n+3) . . . ).

The number of bistable circuits SR of the second shift register 41B is half the number i of pixel rows (i.e., i/2). On the other hand, the number of buffer circuits Buff of the second output buffer unit 42B is the same as the number i of pixel rows (i.e., i). Each of the bistable circuits SR of the second shift register 41B corresponds to two buffer circuits Buff, and controls the two buffer circuits Buff by supplying signals outputted therefrom to the two buffer circuits Buff.

In this way, since each of the first output buffer unit 42A of the first gate driver 40A and the second output buffer unit 42B of the second gate driver 40B has the same number of buffer circuits Buff as the number of pixel rows, the buffer circuits Buff are connected to both ends of each gate bus line GL. The four-phase clock signal is supplied to each of the first gate driver 40A and the second gate driver 40B. An identical gate clock signal is supplied to the two buffer circuits Buff connected to an identical gate bus line GL. Each of the buffer circuits Buff receives the output signal of the corresponding bistable circuit SR and the corresponding gate clock signal, and generates a scanning signal to be supplied to the corresponding gate bus line GL. For example, in the first output buffer unit 42A, the buffer circuit Buff(n) corresponding to the nth gate bus line GL(n) receives the output signal of the bistable circuit S(n) and the first gate clock signal GCK1 to generate a scanning signal, and supplies the scanning signal to the nth gate bus line GL(n). In addition, the buffer circuit Buff(n−1) corresponding to the (n−1)th gate bus line GL(n−1) receives the output signal of the bistable circuit S(n) and the fourth gate clock signal GCK4 to generate a scanning signal, and supplies the scanning signal to the (n−1)th gate bus line GL(n−1).

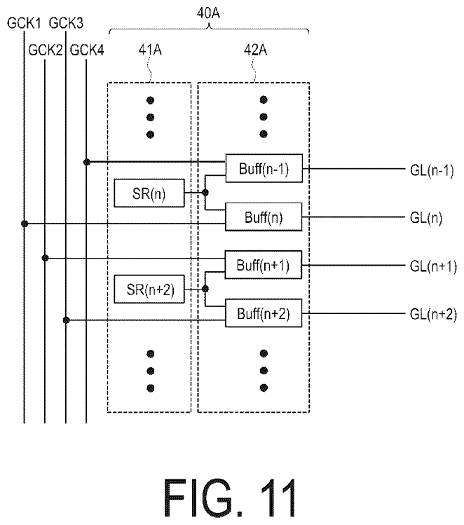

Subsequently, the configuration of the gate driver will be described in more detail by taking the first gate driver 40A as an example. FIG. 11 is a schematic circuit diagram illustrating the configuration of the first gate driver 40A.

The first shift register 41A of the first gate driver 40A includes the bistable circuits SR(n) and SR(n+2) connected in cascade. The output end of the bistable circuit SR(n) is connected to the input end of the buffer circuit Buff(n−1) corresponding to the (n−1)th gate bus line GL(n−1) and to the input end of the buffer circuit Buff(n) corresponding to the nth gate bus line GL(n). The output end of the bistable circuit SR(n+2) is connected to the input end of the buffer circuit Buff(n+1) corresponding to the (n+1)th gate bus line GL(n+1) and to the input end of the buffer circuit Buff(n+2) corresponding to the (n+2)th gate bus line GL(n+2). The fourth gate clock signal GCK4, the first gate clock signal GCK1, the second gate clock signal GCK2, and the third gate clock signal GCK3 are input to the buffer circuits Buff(n−1), Buff(n), Buff(n+1), and Buff(n+2), respectively.

Hereinafter, one bistable circuit SR and two buffer circuits Buff corresponding thereto may be collectively referred to as a “unit circuit”. In the example illustrated in FIG. 11, the bistable circuit SR(n) and the buffer circuits Buff(n−1) and Buff(n) constitute one unit circuit, and bistable circuit SR(n+2) and the buffer circuits Buff(n+1) and Buff(n+2) constitute another one unit circuit.

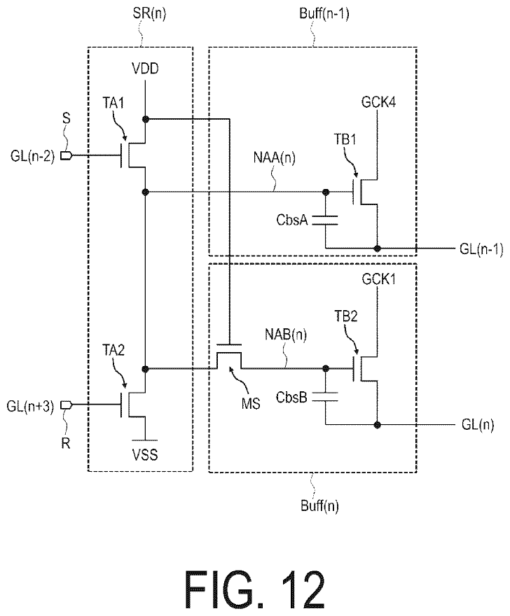

The basic configuration of each unit circuit will be described with reference to FIG. 12. FIG. 12 is a circuit diagram illustrating a basic configuration of a unit circuit including the bistable circuit SR(n). The unit circuit illustrated in FIG. 12 includes the bistable circuit SR(n) and the buffer circuits Buff(n−1) and Buff(n).

The bistable circuit SR(n) includes two N-channel thin film transistors TA1 and TA2. A drain terminal of the thin film transistor TA1 is connected to a high-level power supply line VDD, and a source terminal of the thin film transistor TA2 is connected to a low-level power supply line VSS. A source terminal of the thin film transistor TA1 and a drain terminal of the thin film transistor TA2 are connected to each other, and this connection point corresponds to an output end of the bistable circuit SR(n). Hereinafter, a node NAA(n) including the output end is referred to as a “first state node”.

A gate terminal of the thin film transistor TA1 corresponds to a set terminal S, and a gate terminal of the thin film transistor TA2 corresponds to a reset terminal R. The set terminal S is connected to the (n−2)th gate bus line GL(n−2), and the reset terminal R is connected to the (n+3)th gate bus line GL(n+3).

The bistable circuit SR(n) becomes one of a “set state” and a “reset state” by charging or discharging electric charge to or from the capacitor connected to the first state node NAA(n). Specifically, when a high-level voltage is applied to the set terminal S, the bistable circuit SR(n) becomes the “set state” in which the voltage of the first state node NAA(n) is at a high level. When a high-level voltage is applied to the reset terminal R, the bistable circuit SR(n) becomes the “reset state” in which the voltage of the first state node NAA(n) is at a low level. A high-level signal is output from the output end of the bistable circuit SR(n) in the “set state”.

The buffer circuit Buff(n−1) includes a buffer transistor TB1, which is an N-channel thin film transistor, and a boost capacitor CbsA. The fourth gate clock signal GCK4 is given to a drain terminal of the buffer transistor TB1. A gate terminal of the buffer transistor TB1 corresponds to the input end of the buffer circuit Buff(n−1), and is connected to the first state node NAA(n). A source terminal of the buffer transistor TB1 corresponds to the output end of the buffer circuit Buff(n−1), is connected to the gate terminal of the buffer transistor TB1 via the boost capacitor CbsA, and is also connected to the (n−1)th gate bus line GL(n−1).

The buffer circuit Buff(n) includes a buffer transistor TB2, which is an N-channel thin film transistor, and a boost capacitor CbsB. The buffer circuit Buff(n) further includes an N-channel thin film transistor MS. The first gate clock signal GCK1 is given to a drain terminal of the buffer transistor TB2. A gate terminal of the buffer transistor TB2 is connected to the first state node NAA(n) via the thin film transistor MS. Of the conduction terminals of the thin film transistor MS, the terminal connected to the first state node NAA(n) corresponds to the input end of the buffer circuit Buff(n). A source terminal of the buffer transistor TB2 corresponds to the output end of the buffer circuit Buff(n), is connected to the gate terminal of the buffer transistor TB2 via the boost capacitor CbsB, and is also connected to the (n)th gate bus line GL(n).

A gate terminal of the thin film transistor MS is connected to the high-level power supply line VDD. Hereinafter, the voltage of the high-level power supply line VDD is referred to as a “high-level power supply voltage”, and the high-level power supply voltage is also denoted by the same reference sign VDD. When the threshold voltage of the thin film transistor MS is denoted by Vth(MS), the thin film transistor MS is in an off state when both the voltages of the source terminal and the drain terminal are higher than VDD−Vth(MS).

Therefore, when the buffer transistor TB2 of the buffer circuit Buff(n) is in the on state, even if the pulse of the first gate clock signal GCK1 increases the voltage of the gate terminal of the buffer transistor TB2 via the boost capacitor CbsB, that is, the voltage of the node (hereinafter referred to as a “second state node”) NAB(n) including the gate terminal, the increase in voltage does not affect the voltage of the first state node NAA(n). When the buffer transistor TB1 of the buffer circuit Buff(n−1) is in the on state, even if the pulse of the fourth gate clock signal GCK4 increases the voltage of the gate terminal of the buffer transistor TB1 via the boost capacitor CbsA, that is, the voltage of the first state node NAA(n), the increase in voltage does not affect the voltage of the second state node NAB(n).

This is because the thin film transistor MS operates, on the basis of its characteristics as a field effect transistor, as a transmission gate that transmits a voltage equal to or less than VDD−Vth(MS) and does not transmit a voltage exceeding VDD−Vth(MS). The thin film transistor MS operating as such a transmission gate functions so that a boost effect at one of the first state node NAA(n) and the second state node NAB(n) does not affect the other node. Hereinafter, the thin film transistor MS is also referred to as a “boost isolation transistor”.

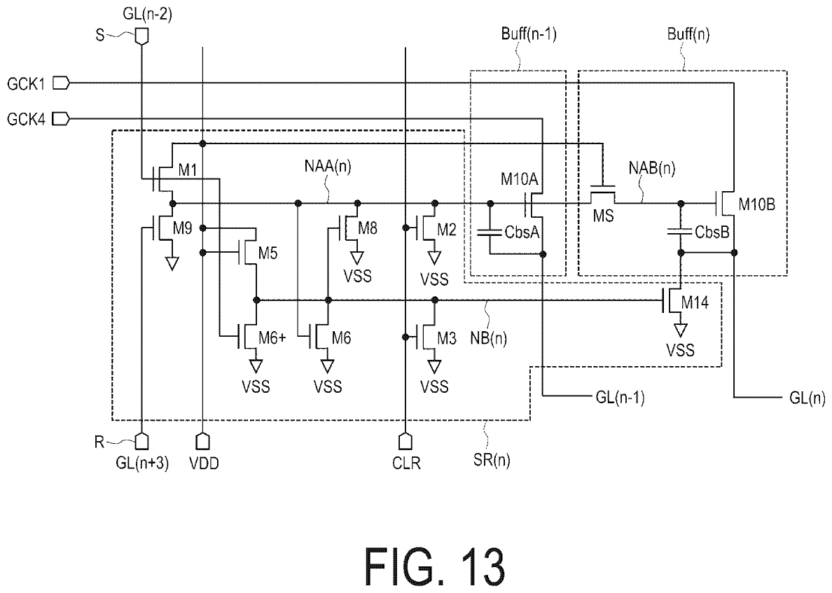

FIG. 13 is a circuit diagram illustrating a detailed configuration of a unit circuit including the bistable circuit SR(n). In the example illustrated in FIG. 13, the bistable circuit SR(n) includes N-channel thin film transistors M1, M2, M3, M5, M6, M6+, M8, M9, and M14. The set terminal S is connected to the (n−2)th gate bus line GL(n−2), and the reset terminal R is connected to the (n+3)th gate bus line GL(n+3).

The thin film transistors M1 and M9 correspond to the thin film transistors TA1 and TA2 illustrated in FIG. 12, respectively. The connection point of the thin film transistors M1 and M9 constitutes an output end of the bistable circuit SR(n) and a node including the output end is the first state node NAA(n).

The bistable circuit SR(n) includes a clear terminal CLR as the input terminal of the clear signal for initialization, the gate terminals of the thin film transistors M2 and M3 are connected to the clear terminal CLR. Note that hereinafter, a node NB(n) including the connection point of the thin film transistors M5 and M6 is referred to as a “third state node”.

The buffer circuit Buff(n−1) has the same configuration as the buffer circuit Buff(n−1) illustrated in FIG. 12, and includes an N-channel thin film transistor (buffer transistor) M10A and the boost capacitor CbsA. The fourth gate clock signal GCK4 is given to a drain terminal of the buffer transistor M10A. A source terminal of the buffer transistor M10A is connected to the (n−1)th gate bus line GL(n−1).

The buffer circuit Buff(n) has the same configuration as the buffer circuit Buff(n) illustrated in FIG. 12, and includes an N-channel thin film transistor (buffer transistor) M10B, the N-channel thin film transistor (boost isolation transistor) MS, and the boost capacitor CbsB. The first gate clock signal GCK1 is given to a drain terminal of the buffer transistor M10B. A source terminal of the buffer transistor M10B is connected to the (n)th gate bus line GL(n). Note that a gate terminal of the buffer transistor M10B is connected to the first state node NAA(n) via the boost isolation transistor MS, and the node including the gate terminal is the second state node NAB(n).

Since the operation of the gate driver having the configuration exemplified here is disclosed in U.S. Patent Application Publication No. 2020/0135132, the description thereof is omitted here. The entire contents of the disclosure of U.S. Patent Application Publication No. 2020/0135132 are incorporated in the present specification by reference.

### Application Example of Structure of Circuit TFT 3

An example in which the structure of the circuit TFT 3 illustrated in FIG. 4 is applied to the unit circuit illustrated in FIG. 13 will be described.

In the unit circuit illustrated in FIG. 13, a high-level power supply voltage is applied to one of the source and drain terminals of the thin film transistor M1, and a low-level voltage is applied to the other in most of one frame. A voltage exceeding the peak-to-peak voltage Vpp of the gate clock signal is applied between the source and the drain of the thin film transistors M2, M8 and M9.

Therefore, it can be said that the thin film transistors M1, M2, M8 and M9 are circuit TFTs for which a particularly high source-drain breakdown voltage is desired. Therefore, it is preferable to adopt the structure of the circuit TFT 3 illustrated in FIG. 4 for the thin film transistors M1, M2, M8 and M9.

In addition, the structure of the circuit TFT 3 may be adopted for a circuit TFT in which a particularly high source-drain breakdown voltage is desired, and tandem arrangement may be performed. As used herein, “tandem arrangement” means replacing one circuit TFT with two or more (i.e., at least one pair of) circuit TFTs connected in series. By replacing each of the thin film transistors M1, M2, M8 and M9 with two or more circuit TFTs 3 connected in series, the reliability of the GDM circuit can be further improved.

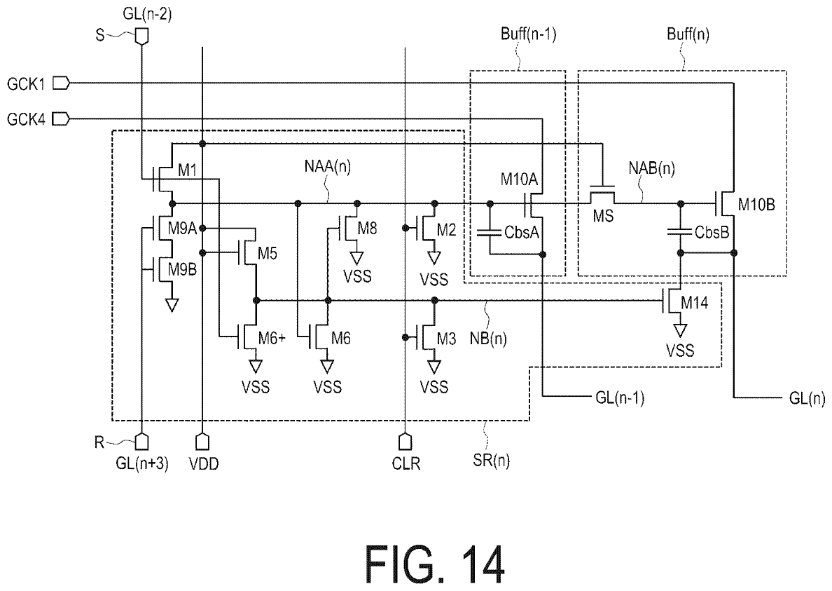

FIG. 14 illustrates a configuration in which the thin film transistor M9 is provided in tandem arrangement. In the example illustrated in FIG. 14, the thin film transistor M9 is replaced with two thin film transistors (circuit TFTs) M9A and M9B connected in series. Note that although the example in which the thin film transistor M9 is provided in tandem arrangement is illustrated here, similarly, the thin film transistors M1, M2, and M8 may be provided in tandem arrangement.

In addition, the structure of the circuit TFT 3 may be adopted for a circuit TFT for which a particularly high source-drain breakdown voltage is desired, and the channel length CL thereof may be made larger than the channel length CL of the other circuit TFTs. This can also further improve the reliability of the GDM circuit. In this case, the circuit TFT having the first channel length CL1 and the circuit TFT having the second channel length CL2 larger than the first channel length CL1 are mixed in the GDM circuit.

### Application Example of Structure of First Circuit TFT 3A and Second Circuit TFT 3B

An example in which the structure of the first circuit TFT 3A and the second circuit TFT 3B illustrated in FIG. 6 is applied to the unit circuit illustrated in FIG. 13 will be described.

As described above, in the unit circuit illustrated in FIG. 13, the thin film transistors M1, M2, M8, and M9 are circuit TFTs for which a particularly high source-drain breakdown voltage is desired. Therefore, it is preferable to adopt the structure of the second circuit TFT 3B illustrated in FIG. 6 for the thin film transistors M1, M2, M8, and M9. The thin film transistors M1, M2, M8 and M9 may be modified to adopt the structure of the second circuit TFT 3B, to perform tandem arrangement, and to make the channel length CL thereof larger than the channel length CL of the other circuit TFTs (in this case, the circuit TFT having the first channel length CL1 and the circuit TFT having the second channel length CL2 larger than the first channel length CL1 are mixed in the GDM circuit).

In the unit circuit illustrated in FIG. 13, a gate clock signal having a duty ratio of about 50% is given to one of the source terminal and the drain terminal of each of the thin film transistors M10A and M10B, and a low-level voltage is applied to the other thereof in most of one frame. Although it is preferable that such thin film transistors M10A and M10B have a high source-drain breakdown voltage, the source-drain breakdown voltage may be slightly lower than that of the thin film transistors M1, M2, M8 and M9. Therefore, by adopting the structure of the first circuit TFT 3A for the thin film transistors M10A and M10B, it is possible to reduce the size of the GDM circuit while ensuring the reliability of the GDM.

### Oxide Semiconductor

An oxide semiconductor (also referred to as a metal oxide, or an oxide material) included in the oxide semiconductor layer of the oxide semiconductor TFT may be an amorphous oxide semiconductor or a crystalline oxide semiconductor including a crystalline portion. Examples of the crystalline oxide semiconductor include a polycrystalline oxide semiconductor, a microcrystalline oxide semiconductor, and a crystalline oxide semiconductor having a c-axis oriented substantially perpendicular to the layer surface.

Materials, structures, and film formation methods of an amorphous oxide semiconductor and the above-described crystalline oxide semiconductors, a configuration of an oxide semiconductor layer having a layered structure, and the like are described in, for example, JP 2014-007399 A. The entire contents of the disclosure of JP 2014-007399 A are incorporated in the present specification by reference.

The oxide semiconductor layer may include, for example, at least one metal element selected from In, Ga, and Zn. In the present embodiment, the oxide semiconductor layer includes, for example, an In—Ga—Zn—O-based semiconductor (for example, an indium gallium zinc oxide). Here, the In—Ga—Zn—O-based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. Such an oxide semiconductor layer can be formed of an oxide semiconductor film including an In—Ga—Zn—O-based semiconductor.

The In—Ga—Zn—O-based semiconductor may be an amorphous semiconductor or may be a crystalline semiconductor. A crystalline In—Ga—Zn—O-based semiconductor in which a c-axis is oriented substantially perpendicular to a layer surface is preferable as the crystalline In—Ga—Zn—O-based semiconductor.

Note that a crystal structure of the crystalline In—Ga—Zn—O-based semiconductor is disclosed, for example, in JP 2014-007399 A described above, JP 2012-134475 A, JP 2014-209727 A, and the like. The entire contents of the disclosures of JP 2012-134475 A and JP 2014-209727 A are incorporated in the present specification by reference. A TFT including an In—Ga—Zn—O-based semiconductor layer has a high mobility (more than 20 times as compared to an a-Si TFT) and a low leakage current (less than 1/100 as compared to the a-Si TFT). Thus, such a TFT can be suitably used as a drive TFT (for example, a TFT included in a drive circuit provided in a periphery of a display region including a plurality of pixels, and on the same substrate as the display region) and a pixel TFT (TFT provided in a pixel).

In place of the In—Ga—Zn—O-based semiconductor, the oxide semiconductor layer may include another oxide semiconductor. There may be included, for example, an In—Sn—Zn—O-based semiconductor (for example, In₂O₃—SnO₂—ZnO; InSnZnO). The In—Sn—Zn—O-based semiconductor is a ternary oxide of In (indium), Sn (tin), and Zn (zinc). Alternatively, the oxide semiconductor layer may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, cadmium oxide (CdO), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, an In—Ga—Zn—Sn—O-based semiconductor, an In—W—Zn—O-based semiconductor, and the like.

### INDUSTRIAL APPLICABILITY

According to an embodiment of the disclosure, it is possible to provide an active matrix substrate that includes a scanning signal line drive circuit including an oxide semiconductor TFT and that can achieve both a high source-drain breakdown voltage and a high mobility of the oxide semiconductor TFT.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An active matrix substrate comprising:
a substrate;
a plurality of scanning signal lines supported by the substrate; and
a scanning signal line drive circuit configured to drive the plurality of scanning signal lines, the scanning signal line drive circuit including a plurality of oxide semiconductor TFTs,
wherein the plurality of oxide semiconductor TFTs include a plurality of first oxide semiconductor TFTs,
each of the first oxide semiconductor TFTs includes
a first oxide semiconductor layer including a channel region, and a first contact region and a second contact region located on both sides of the channel region,
a first gate electrode disposed on the channel region of the first oxide semiconductor layer with a first gate insulating layer interposed between the first gate electrode and the first oxide semiconductor layer,
a first source electrode electrically connected to the first contact region, and
a first drain electrode electrically connected to the second contact region,
the first oxide semiconductor layer has a layered structure including a first layer and a second layer that is located between the first layer and the first gate insulating layer, is an uppermost layer of the first oxide semiconductor layer, and has a lower mobility than the first layer, and
a thickness of the second layer in the channel region is equal to or more than 3.4% of a thickness of the first gate insulating layer.

2. The active matrix substrate according to claim 1,
wherein a thickness of the second layer in the channel region is equal to or more than 5 nm.

3. The active matrix substrate according to claim 1,
wherein the first oxide semiconductor layer further includes a third layer located on a side opposite to the second layer with respect to the first layer, the third layer having a lower mobility than the first layer.

4. The active matrix substrate according to claim 1,
wherein the plurality of first oxide semiconductor TFTs include at least a pair of first oxide semiconductor TFTs connected in series.

5. The active matrix substrate according to claim 1,
wherein the plurality of oxide semiconductor TFTs include an oxide semiconductor TFT having a first channel length CL1, and
the plurality of first oxide semiconductor TFTs include a first oxide semiconductor TFT having a second channel length CL2 larger than the first channel length CL1.

6. The active matrix substrate according to claim 1,
wherein the plurality of oxide semiconductor TFTs further include a plurality of second oxide semiconductor TFTs, and
each of the second oxide semiconductor TFTs includes
a second oxide semiconductor layer different from the first oxide semiconductor layer, the second oxide semiconductor layer having a lower mobility than the first layer of the first oxide semiconductor layer, and
a second gate electrode disposed on a part of the second oxide semiconductor layer with a second gate insulating layer interposed between the second gate electrode and the second oxide semiconductor layer.

7. The active matrix substrate according to claim 6,
wherein the plurality of second oxide semiconductor TFTs include at least one pair of second oxide semiconductor TFTs connected in series.

8. The active matrix substrate according to claim 6,
wherein the plurality of oxide semiconductor TFTs include an oxide semiconductor TFT having a first channel length CL1, and
the plurality of second oxide semiconductor TFTs include a second oxide semiconductor TFT having a second channel length CL2 larger than the first channel length CL1.

9. The active matrix substrate according to claim 1,
wherein the first gate insulating layer overlaps neither the first contact region nor the second contact region of the first oxide semiconductor layer in a plan view.

10. The active matrix substrate according to claim 1, further comprising:
an upper insulating layer covering the first oxide semiconductor layer and the first gate electrode,
wherein the upper insulating layer includes a source contact hole for electrically connecting the first source electrode to the first contact region and a drain contact hole for electrically connecting the first drain electrode to the second contact region, and
the second layer of the first oxide semiconductor layer is present at least in a region of the first contact region not overlapping the source contact hole, and is present at least in a region of the second contact region not overlapping the drain contact hole.

11. The active matrix substrate according to claim 1,
wherein the second layer of the first oxide semiconductor layer is removed in a part of the first contact region and a part of the second contact region, and
the first source electrode and the first drain electrode each are in direct contact with the first layer of the first oxide semiconductor layer.

12. The active matrix substrate according to claim 1,
wherein the scanning signal line drive circuit is monolithically formed on the active matrix substrate.

13. The active matrix substrate according to claim 1,
wherein the first oxide semiconductor layer includes an In—Ga—Zn—O-based semiconductor.

14. A display device comprising:
the active matrix substrate according to claim 1.

15. A method of manufacturing the active matrix substrate according to claim 1, comprising:
(A) forming the first oxide semiconductor layer;
(B) after the (A), depositing an insulating film on the first oxide semiconductor layer; and
(C) after the (B), forming the first gate insulating layer by etching the insulating film,
wherein a thickness of the second layer of the first oxide semiconductor layer formed in the (A) is set to cause the second layer to remain over an entire region serving as the first contact region and an entire region serving as the second contact region when the (C) is completed.
